(19) United States
(12) Patent Application Publication
(10) Pub. No.: US 2026/0164639 A1
(43) Pub. Date: Jun. 11, 2026

(54) SEMICONDUCTOR DEVICE

(71) Applicant: SAMSUNG ELECTRONICS CO., LTD., Suwon-si (KR)

(72) Inventors: TAEJIN PARK, Suwon-si (KR); Taekyong Kim, Suwon-si (KR); Taeyoon An, Suwon-si (KR); Sung Soo Yim, Suwon-si (KR)

(73) Assignee: SAMSUNG ELECTRONICS CO., LTD., Suwon-si (KR)

(21) Appl. No.: 19/183,413

(22) Filed: Apr. 18, 2025

(30) Foreign Application Priority Data
Oct. 10, 2024 (KR) 10-2024-0137806

(51) Int. Cl. H10B 12/00; H10D 1/68

(52) U.S. Cl. CPC H10B 12/315; H10B 12/482; H10B 12/488; H10D 1/716; H10B 12/0335; H10B 12/05

(57) ABSTRACT

There is provided a semiconductor device including a bit line that extends in a first direction, a plurality of semiconductor patterns providing on the bit line and extend in a second direction perpendicular to a top surface of the bit line, a first word line and a second word line between the semiconductor patterns and spaced apart from each other in the first direction wherein the first and second word lines extend in a third direction perpendicular to the first direction and the second direction, a plurality of storage node contacts on the semiconductor patterns; and a metal pattern between the storage node contacts.

### CROSS-REFERENCE TO RELATED APPLICATION

This application is based on and claims priority under 35 U.S.C § 119 to Korean Patent Application No. 10-2024-0137806 filed on Oct. 10, 2024 in the Korean Intellectual Property Office, the disclosure of which is hereby incorporated by reference in its entirety.

### BACKGROUND

The disclosure relates to a semiconductor device, and more particularly, to a semiconductor device including vertical channel transistors and a method of fabricating the same.

In semiconductor fabrication technology, a reduction in design rule of semiconductor devices leads to increase integration, operating speeds, and manufacturing yield of semiconductor devices. Accordingly, transistors with vertical channels have been suggested to increase their integration, resistance, current driving capability, and so forth.

### SUMMARY

Aspects of the disclosure provide a semiconductor device with improved reliability and electrical characteristics and a method of fabricating the same.

According to an aspect of the disclosure, there is provided a semiconductor device, including: a bit line that extends in a first direction; a plurality of semiconductor patterns provided on the bit line, the plurality of semiconductor patterns extending in a second direction perpendicular to an upper surface of the bit line; a first word line and a second word line between the semiconductor patterns and spaced apart from each other in the first direction, the first and second word lines extending in a third direction perpendicular to the first direction and the second direction; a plurality of storage node contacts provided on the plurality of semiconductor patterns; and a metal pattern between the plurality of storage node contacts.

According to another aspect of the disclosure, there is provided a semiconductor device, including: a bit line that extends in a first direction; a plurality of semiconductor patterns provided on the bit line, the plurality of semiconductor patterns extending in a second direction perpendicular to an upper surface of the bit line; a first word line and a second word line between the semiconductor patterns and spaced apart from each other in the first direction, the first and second word lines extending in a third direction perpendicular to the first direction and the second direction; a plurality of storage node contacts provided on the plurality of semiconductor patterns; and a metal pattern between the plurality of storage node contacts, wherein a bottom surface of the metal pattern is at a first level lower than a second level of bottom surfaces of the plurality of storage node contacts.

According to another aspect of the disclosure, there is provided a semiconductor device, including: a bit line that extends in a first direction; a plurality of semiconductor patterns provided on the bit line, the plurality of semiconductor patterns extending in a second direction perpendicular to an upper surface of the bit line; a first word line and a second word line between the semiconductor patterns and spaced apart from each other in the first direction, the first and second word lines extending in a third direction perpendicular to the first direction and the second direction; a plurality of storage node contacts provided on the plurality of semiconductor patterns; and a metal pattern spaced apart in the first direction or the third direction from the plurality of storage node contacts, wherein the metal pattern extends in the first direction and the third direction.

### BRIEF DESCRIPTION OF DRAWINGS

FIG. 1 illustrates a block diagram showing a semiconductor device according to some embodiments of the disclosure.

FIGS. 2 and 3 illustrate perspective views showing a semiconductor device according to some embodiments of the disclosure.

FIG. 4 illustrates a plan view showing a semiconductor device according to some embodiments of the disclosure.

FIGS. 5A, 5B, and 5C illustrate cross-sectional views respectively taken along lines A-A′, B-B′, and C-C′ of FIG. 4, showing a semiconductor device according to some embodiments of the disclosure.

FIGS. 6A, 6B, and 6C illustrate cross-sectional views respectively taken along lines A-A′, B-B′, and C-C′ of FIG. 4, showing a semiconductor device according to some embodiments of the disclosure.

FIGS. 7A, 7B, and 7C illustrate cross-sectional views respectively taken along lines A-A′, B-B′, and C-C′ of FIG. 4, showing a semiconductor device according to some embodiments of the disclosure.

FIGS. 8A, 8B, and 8C illustrate cross-sectional views respectively taken along lines A-A′, B-B′, and C-C′ of FIG. 4, showing a semiconductor device according to some embodiments of the disclosure.

FIGS. 9A to 9C, 10A to 10C, 11A to 11C, 12A to 12C, 13A to 13C, 14A to 14C, 15A to 15C, 16A to 16C, 17A to 17C, 18A to 18C and 19A to 19C illustrate cross-sectional views showing a method of fabricating a semiconductor device according to some embodiments of the disclosure.

### DETAILED DESCRIPTION

Some embodiments of the disclosure will now be described in detail with reference to the accompanying drawings to aid in clearly explaining the inventive concepts.

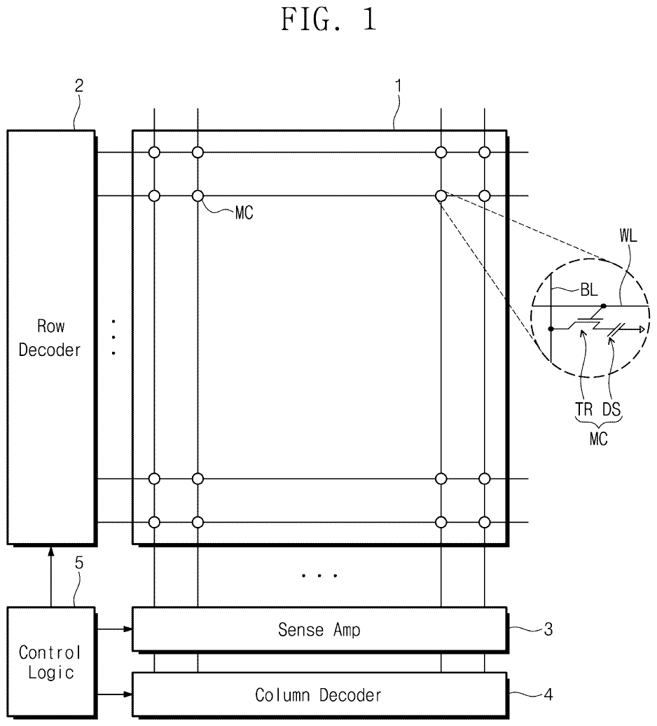

FIG. 1 illustrates a block diagram showing a semiconductor device according to some embodiments of the disclosure.

Referring to FIG. 1, a semiconductor device may include a memory cell array 1, a row decoder 2, a sense amplifier 3, a column decoder 4, and a control logic 5. However, the disclosure is not limited thereto, and as such, according to an embodiment, the semiconductor device may include one or more other components or circuits.

The memory cell array 1 may include a plurality of memory cells MC that are arranged two-dimensionally or three-dimensionally. Each of the memory cells MC may be connected between a word line WL and a bit line BL that intersect each other. The semiconductor device may include a plurality word lines WL and a plurality of bit lines BL.

Each of the memory cells MC may include a selection element TR and a data storage element DS. The selection element TR and the data storage element DS may be electrically connected to each other. The selection element TR may be connected to both of the word line WL and the bit line BL. For example, the selection element TR may be provided at an intersection between the word line WL and the bit line BL.

The selection element TR may include, but is not limited to, a field effect transistor. The data storage element DS may include, but is not limited to, a capacitor, a magnetic tunnel junction pattern, or a variable resistor. For example, a gate terminal of a transistor as the selection element TR may be connected to the word line WL, and source/drain terminals of the transistor may be connected to the bit line BL and the data storage element DS.

The row decoder 2 may decode an address that is externally input and may select one of the word lines WL of the memory cell array 1. The address decoded in the row decoder 2 may be provided to a row driver, and based on a control operation of control circuits, the row driver may provide a certain voltage to a selected word line WL and each of non-selected word lines WL. For example, in response to a control operation of control circuits, the row driver may provide a certain voltage to a selected word line WL and each of non-selected word lines WL.

According to an embodiment, based on an address decoded from the column decoder 4, the sense amplifier 3 may detect and amplify a voltage difference between a selected bit line BL and a reference bit line, and may then output the amplified voltage difference. For example, in response to an address decoded from the column decoder 4, the sense amplifier 3 may detect and amplify the voltage difference between the selected bit line BL and the reference bit line.

The column decoder 4 may provide a data delivery pathway between the sense amplifier 3 and an external device. The external device may include, but is not limited toa memory controller. The column decoder 4 may decode an address externally input and may select one of the plurality of bit lines BL.

The control logic 5 may generate control signals that control operations to write data to the memory cell array 1 and/or to read data from the memory cell array 1. The control logic 5 is not limited thereto, and as such, according to another embodiment, the control logic 5 may be configured to perform other operations.

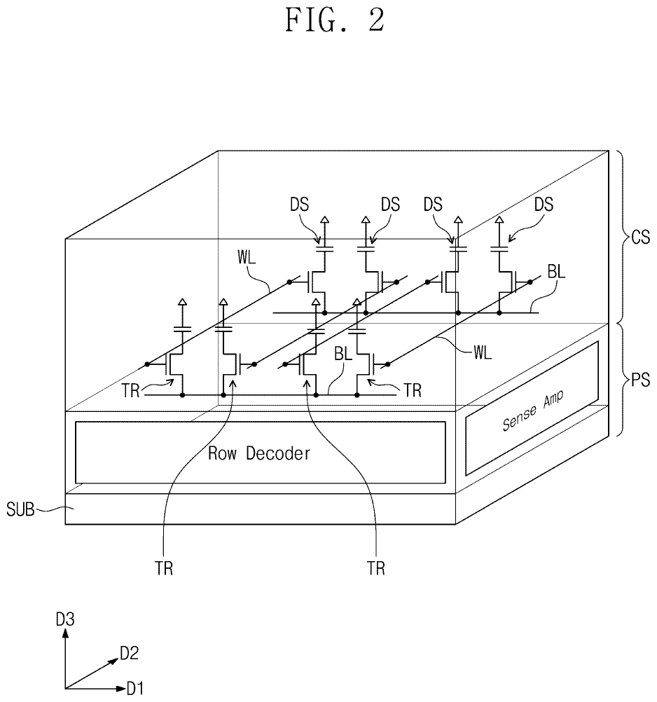

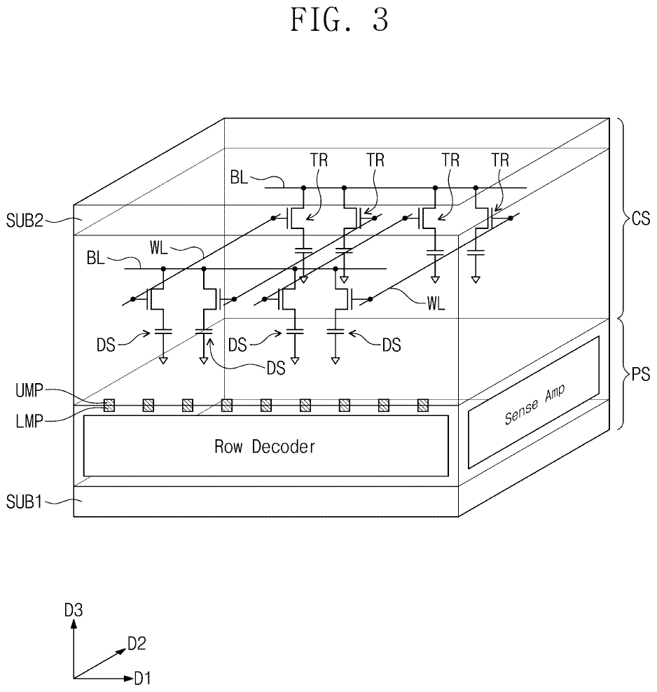

FIGS. 2 and 3 illustrate perspective views showing a semiconductor device according to some embodiments.

Referring to FIGS. 2 and 3, a semiconductor device may include a peripheral circuit structure PS and a cell structure CS connected to the peripheral circuit structure PS.

The peripheral circuit structure PS may include peripheral circuits formed on a substrate SUB. The peripheral circuits may include the row decoder 2, the sense amplifier 3, column decoder 4, and the control logic 5 that are discussed with reference to FIG. 1. The peripheral circuits may be referred to as core circuits.

The cell structure CS may include a memory cell array (see 1 of FIG. 1) including two-dimensionally or three-dimensionally arranged memory cells (see MC of FIG. 1). Each of the memory cells (see MC of FIG. 1) may include a selection element TR and a data storage element DS as discussed above.

In some embodiments, a vertical channel transistor (VCT) may be included as the selection element TR of each memory cell (see MC of FIG. 1). The vertical channel transistor may include a channel having lengthwise direction that is perpendicular to a top surface of the substrate SUB. The data storage element DS of each of the memory cells (see MC of FIG. 1) may include a capacitor.

According to an embodiment illustrated in FIG. 2, the peripheral circuit structure PS may be provided on the substrate SUB, and the cell structure CS may be provided on the peripheral circuit structure PS.

According to an embodiment illustrated in FIG. 3, the peripheral circuit structure PS may be provided on a first substrate SUB1, and the cell structure CS may be provided on a second substrate SUB2. The first substrate SUB1 and the second substrate SUB2 may face each other. For example, the first substrate SUB1 may provide on a first side of the semiconductor device and the second substrate SUB2 may be provided on a second side of the semiconductor device opposite to the first side.

The peripheral circuit structure PS may be provided with first metal pads LMP on an uppermost portion of the peripheral circuit structure PS. The first metal pads LMP may be electrically connected to the peripheral circuits. For example, the first metal pads LMP may be electrically connected to the row decoder 2, the sense amplifier 3, the column decoder 4, and the control logic 5 illustrated in FIG. 1.

The cell structure CS may be provided with second metal pads UMP on a lowermost portion of the cell structure CS. The second metal pads UMP may be electrically connected to the memory cell array (see 1 of FIG. 1). The second metal pads UMP may be in contact with the first metal pads LMP of the peripheral circuit structure PS. For example, the second metal pads UMP may be in direct contact with and bonded to the first metal pads LMP of the peripheral circuit structure PS.

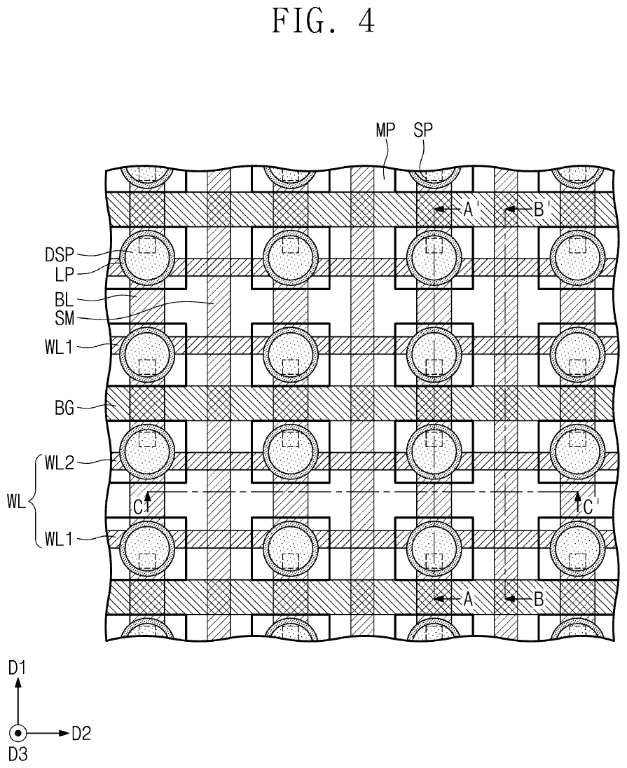

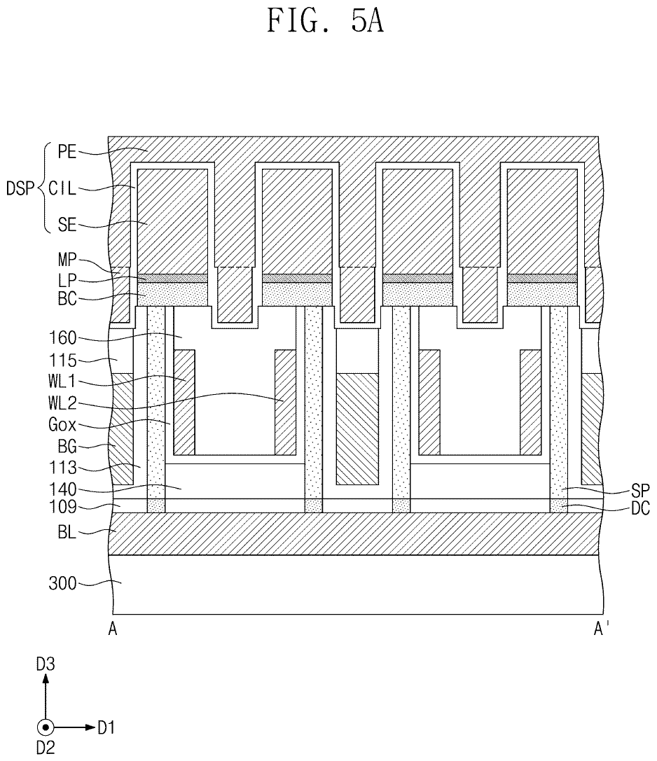

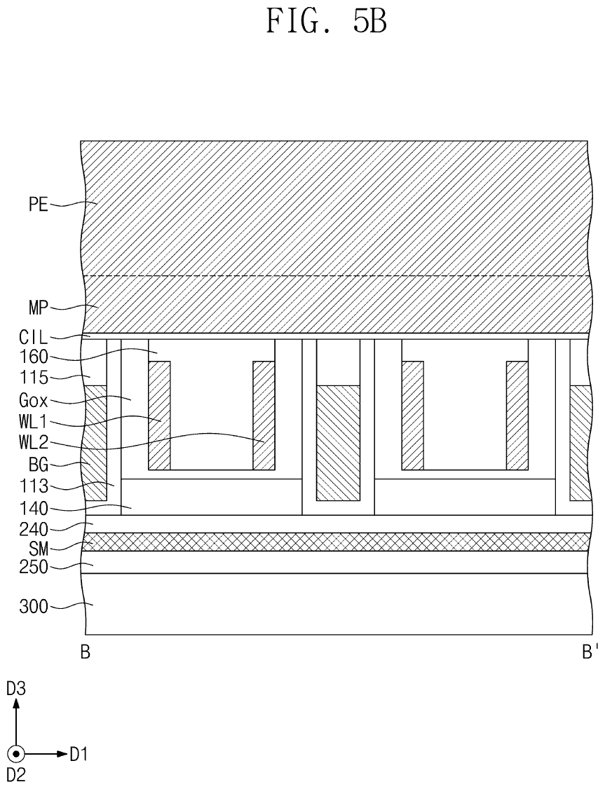

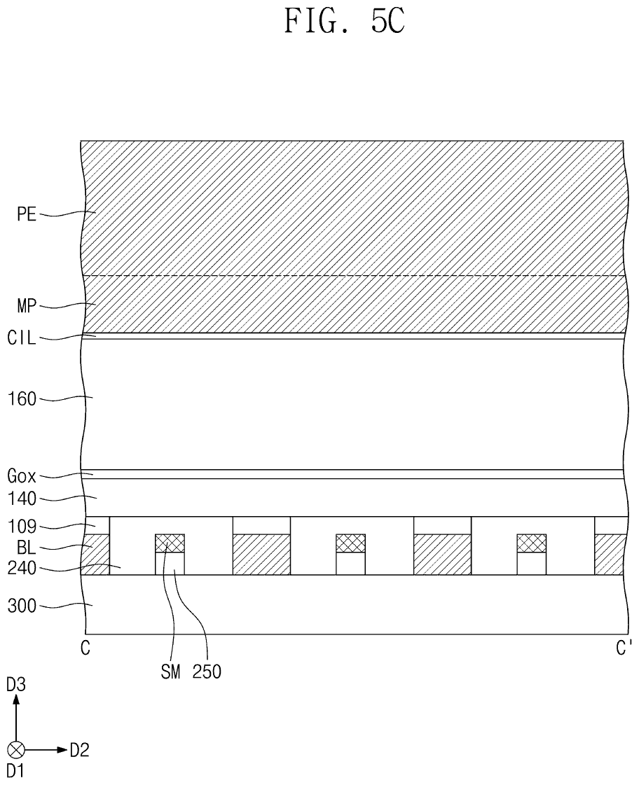

FIG. 4 illustrates a plan view showing a semiconductor device according to some embodiments of the disclosure. FIGS. 5A, 5B, and 5C illustrate cross-sectional views respectively taken along lines A-A′, B-B′, and C-C′ of FIG. 4.

A semiconductor device according to some embodiments of the disclosure may include memory cells including vertical channel transistors (VCT).

Referring to FIGS. 4, 5A, 5B, and 5C, the semiconductor device may include a substrate 300, and a bit line BL provided on the substrate 300. The bit line BL may extend in a first direction D1.

The substrate 300 may be one of a material having semiconductor characteristics, a dielectric material, and a conductor or semiconductor covered with a dielectric material. For example, the material having semiconductor characteristics may include, but is not limited to silicon wafer, and the dielectric material may include, but is not limited to glass.

The bit line BL may be provided in plural. That is, a plurality of bit lines BL may be provided. The plurality of bit lines BL may extend in the first direction D1. The plurality of bit lines BL may be spaced apart from each other in a second direction D2. According to an embodiment, the first direction D1 and the second direction D2 may be directions that are parallel to uppermost surfaces of the bit line BL and cross each other. For example, the first direction D1 and the second direction D2 may intersect each other. A third direction D3 may be a vertical direction that is perpendicular to the uppermost surface of the bit line BL. For example, the first, second, and third directions D1, D2, and D3 may be directions that are perpendicular to each other.

The bit line BL may include a conductive material. For example, the bit line BL may include at least one selected from doped semiconductor materials, metal materials, metal silicides, and metal nitride. For example, the doped semiconductor materials may include, but is not limited to, doped silicon or doped germanium, the metal materials may include, but is not limited to, Ti, Mo, W, Cu, Al, Ta, Ru, Ir, or Co, the metal silicides may include, but is not limited to, silicide of Ti, Mo, W, Cu, Al, Ta, Ru, Ir, or Co, and the metal nitride may include, but is not limited to, nitride of Ti, Mo, W, Cu, Al, Ta, Ru, Ir, or Co. The bit line BL may be a single layer or a composite layer.

According to an embedment, shield structures SM may be provided between the plurality of bit lines BL. For example, shield structures SM may shield potentials of the plurality of bit lines BL. The shield structure SM may extend along the first direction D1. The shield structures SM may include a conductive material, such as metal. The shield structures SM may be provided between a first dielectric layer 240 and a second dielectric layer 250. Each of the first and second dielectric layers 240 and 250 may include multi-layered dielectric layers, and may include at least one selected from silicon oxide, silicon nitride, silicon oxynitride, and low-k dielectrics.

For example, the shield structures SM may be formed of a conductive material, which may include an air gap or a void in the shield structures SM. However, the disclosure is not limited thereto. As such, according to another embodiment air gaps may be provided to substitute for the shield structures SM.

A first dielectric pattern 109 may be provided on the plurality of bit lines BL. The first dielectric pattern 109 may be provided in plural. The first dielectric patterns 109 may include multi-layered dielectric layers. For example, the first dielectric patterns may include, but is not limited to, a material selected from silicon oxide, silicon nitride, silicon oxynitride, and low-k dielectrics.

A bit-line contact DC may be provided on the bit line BL. The bit-line contact DC may be between the bit line BL and a semiconductor pattern SP. For example, the bit-line contact DC may be interposed between the bit line BL and a semiconductor pattern SP as described below. Accordingly, the bit line BL may be connected through the bit-line contact DC to the semiconductor pattern SP.

The bit-line contact DC may include a conductive material. For example, the bit-line contact DC may include doped silicon. The bit-line contact DC may be provided in plural. That is, a plurality of bit-line contacts DC may be provided. For example, the plurality of bit-line contacts DC may be spaced apart along the first direction D1 from each other on one bit line BL.

A semiconductor pattern SP may be provided on the bit line BL. For example, the semiconductor pattern SP may be provided on a top surface of the bit-line contact DC. The semiconductor pattern SP may extend along the third direction D3 on the bit line BL.

The semiconductor pattern SP may be provided in plural. That is, a plurality of semiconductor patterns SP may be provided. For example, the plurality of semiconductor patterns SP may be spaced apart along the first direction D1 from each other on one bit line BL. The plurality of semiconductor patterns SP may be spaced apart from each other along the second direction D2.

The semiconductor pattern SP may include a semiconductor material. The semiconductor pattern SP may include a monocrystalline semiconductor material. For example, the semiconductor pattern SP may include at least one selected from silicon, germanium, and silicon-germanium. For example, the silicon may be monocrystalline silicon, but the disclosure is not limited thereto.

For example, the semiconductor pattern SP may include, but is not limited to, an oxide semiconductor. The oxide semiconductor may include, but is not limited to, at least one selected from InGaZnO, InGaSiO, InSnZnO, InZnO, ZnO, ZnSnO, ZnON, ZrZnSnO, SnO, HfInZnO, GaZnSnO, AlZnSnO, YbGaZnO, and InGaO, but the disclosure are not limited thereto. For example, the semiconductor pattern SP may include indium-gallium-zinc oxide (IGZO).

For example, the semiconductor pattern SP may include a two-dimensional semiconductor material. The two-dimensional semiconductor material may include, but is not limited to, graphene, carbon nano-tube, or a combination thereof.

A word line WL may be provided between the plurality of semiconductor patterns SP. The word line WL may be interposed between the semiconductor patterns SP that are adjacent to (or neighbor) each other in the first direction D1. The word line WL may be provided in plural. The word lines WL may each extend along the second direction D2 and may be spaced apart from each other in the first direction D1.

Each of the word lines WL may include a first word line WL1 and a second word line WL2. A pair of the first word line WL1 and the second word line WL2 that are adjacent in the first direction D1 may be spaced apart from each other across a second dielectric pattern 160. The second dielectric pattern 160 may include at least one selected from silicon oxide, silicon nitride, silicon oxynitride, and low-k dielectrics.

The semiconductor pattern SP may separate the first and second word lines WL1 and WL2 from a back gate electrode BG which will be discussed below.

The word line WL may include, for example, at least one selected from doped polysilicon, metal, conductive metal nitride, conductive metal silicide, and conductive metal oxide, but the disclosure are not limited thereto. For example, the doped polysilicon, metal may include, but is not limited to, Al, Cu, Ti, Ta, Ru, W, Mo, Pt, Ni, or Co, the conductive metal nitride may include, but is not limited to, TiN, TaN, WN, NbN, TiAIN, TiSiN, TaSiN, or RuTiN, and the conductive metal oxide may include, but is not limited to, PtO, RuO₂, IrO₂, SRO (SrRuO₃), BSRO ((Ba,Sr) RuO₃), CRO (CaRuO₃), or LSCo. The word line WL may include a single layer or a multiple layer of the materials discussed above. In some embodiments, the word line WL may include a two-dimensional semiconductor material, such as graphene, carbon nano-tube, or a combination thereof.

According to an embodiment, a back gate electrode BG may be provided on the bit line BL. For example, the back gate electrode BG may extend in the second direction D2 while crossing the bit line BL. The back gate electrode BG may be provided between the plurality of semiconductor patterns SP that neighbor each other in the first direction D1. The back gate electrode BG may be provided in plural. The back gate electrodes BG may be spaced apart from each other in the first direction D1. For example, the back gate electrodes BG may be provided spaced apart from each other in the first direction D1 across the plurality of semiconductor patterns SP that are aligned in the second direction D2.

The back gate electrode BG may include, but is not limited to, doped polysilicon, conductive metal nitride, metal, conductive metal silicide, conductive metal oxide, or a combination thereof. For example, the conductive metal nitride may include, but is not limited to, titanium nitride or tantalum nitride and the metal may include, but is not limited to, tungsten, titanium, or tantalum.

A back gate dielectric pattern 113 may be between the back gate electrode BG and the semiconductor pattern SP. For example, the back gate dielectric pattern 113 may be interposed between the back gate electrode BG and the semiconductor pattern SP that are adjacent to each other. The back gate dielectric pattern 113 may extend between the back gate electrode BG and the first dielectric pattern 109. The back gate dielectric pattern 113 may extend in the third direction D3 between the back gate electrode BG and the semiconductor pattern SP. For example, the back gate dielectric pattern 113 may include vertical parts provided on opposite lateral surfaces facing in the first direction D1 of the back gate electrode BG. For example, the back gate dielectric pattern 113 may include vertical parts that extend in the third direction D3 to cover opposite lateral surfaces facing in the first direction D1 of the back gate electrode BG, and may also include a horizontal part that connect the vertical parts to each other. The back gate dielectric pattern 113 may be provided in plural. The back gate dielectric patterns 113 may extend in the second direction D2 and may be spaced apart from each other in the first direction D1.

The back gate dielectric pattern 113 may include at least one selected from silicon oxide, silicon oxynitride, and high-k dielectrics whose dielectric constant is greater than that of silicon oxide. The high-k dielectrics may include metal oxide or metal oxynitride. For example, the high-k dielectrics possibly used as the back gate dielectric pattern 113 may include at least one selected from HfO₂, HfSiO, HfSiON, HfTaO, HfTIO, HfZrO, ZrO₂, and Al₂O₃, but the disclosure are not limited thereto.

A back gate capping pattern 115 may be provided on the back gate electrode BG. The back gate capping pattern 115 may be provided between the vertical parts of the back gate dielectric pattern 113. The back gate capping pattern 115 may include a dielectric material. The back gate capping pattern 115 may be provided in plural. The back gate capping patterns 115 may extend in the second direction D2, and may be spaced apart from each other in the first direction D1.

A gate dielectric pattern Gox may be between the semiconductor pattern SP and the word line WL. The gate dielectric pattern Gox may be interposed between the semiconductor pattern SP and the word line WL that are adjacent to each other. The gate dielectric pattern Gox may separate the word line WL from the semiconductor pattern SP.

The gate dielectric pattern Gox may include at least one selected from silicon oxide, silicon oxynitride, and high-k dielectrics whose dielectric constant is greater than that of silicon oxide. The high-k dielectrics may include metal oxide or metal oxynitride. For example, the high-k dielectrics possibly used as the gate dielectric pattern Gox may include at least one selected from HfO₂, HfSiO, HfSiON, HfTaO, HfTIO, HfZrO, ZrO₂, and Al₂O₃, but the disclosure are not limited thereto.

A third dielectric pattern 140 may be provided between the first dielectric pattern 109 and a horizontal part of the gate dielectric pattern Gox. The third dielectric pattern 140 may be provided between the back gate electrodes BG. The third dielectric pattern 140 may be provided in plural. The third dielectric patterns 140 may extend in the second direction D2 and may be spaced apart from each other in the first direction D1. The third dielectric pattern 140 may include at least one selected from silicon oxide, silicon nitride, silicon oxynitride, and low-k dielectrics.

A second dielectric pattern 160 may be provided between a first word line WL1 and a second word line WL2. The second dielectric pattern 160 may be provided in plural. The second dielectric patterns 160 may extend in the second direction D2 and may be spaced apart from each other in the first direction D1. The second dielectric pattern 160 may include at least one selected from silicon oxide, silicon nitride, silicon oxynitride, and low-k dielectrics.

A storage node contact BC may be provided on the semiconductor pattern SP. The storage node contact BC may be provided in plural. The storage node contact BC may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSIN, RuTiN, NiSi, CoSi, IrOx, RuOx, or a combination thereof, but the disclosure are not limited thereto.

A landing pad LP may be provided on the semiconductor pattern SP. The landing pad LP may be provided on the storage node contact BC. The landing pad LP may be provided in plural. When viewed in plan, each of the landing pads LP may have a circular shape, an oval shape, a rectangular shape, a square shape, a rhombic shape, a hexagonal shape, or any other suitable shape. The landing pads LP may be formed of doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrOx, RuOx, or a combination thereof, but the disclosure are not limited thereto.

A data storage pattern DSP may be provided on the landing pads LP. The data storage pattern DSP may be correspondingly electrically connected through the landing pads LP to the plurality of semiconductor patterns SP. The data storage pattern DSP may be a capacitor. The data storage pattern DSP may include storage electrodes SE, a plate electrode PE, and a capacitor dielectric layer CIL between the storage electrodes SE and the plate electrode PE. In this case, the storage node electrode SE may be in contact with the landing pad LP.

The storage electrodes SE may be correspondingly provided on the landing pads LP. The storage electrodes SE may include at least selected from metal, metal nitride, and metal silicide. The storage electrodes SE may be spaced apart from each other in the first direction D1 and the second direction D2.

The capacitor dielectric layer CIL may be provided on surfaces of the storage electrodes SE. For example, the capacitor dielectric layer CIL may conformally cover surfaces of the storage electrodes SE. The capacitor dielectric layer CIL may cover top and lateral surfaces of the storage electrodes SE, lateral surfaces of the landing pads LP, and lateral surfaces of the storage node contacts BC. The capacitor dielectric layer CIL may be between the plate electrode PE and the storage electrodes SE. The capacitor dielectric layer CIL may be provided on lateral and bottom surfaces of a metal pattern MP. For example, the capacitor dielectric layer CIL may cover lateral and bottom surfaces of a metal pattern MP which will be discussed below. The capacitor dielectric layer CIL may be between the metal pattern MP and the landing pads LP, between the metal pattern MP and the storage node contacts BC, between the metal pattern MP and the second dielectric pattern 160, between the metal pattern MP and the back gate dielectric pattern 113, and between the metal pattern MP and the back gate capping pattern 115.

The capacitor dielectric layer CIL may include at least one selected from silicon oxide, silicon oxynitride, high-k dielectrics whose dielectric constant is greater than that of silicon oxide, metal oxide such as hafnium oxide, zirconium oxide, aluminum oxide, lanthanum oxide, tantalum oxide, and titanium oxide, and perovskite-structured dielectrics such as SrTiO₃(STO), (Ba,Sr)TiO₃ (BST), BaTiO₃, PZT, and PLZT. The capacitor dielectric layer CIL may be provided in the form of a single layer or a multiple layer.

The plate electrode PE may be provided on the capacitor dielectric layer CIL. The plate electrode PE may be provided on the storage electrodes SE. The plate electrode PE may cover in common the storage electrodes SE that are provided spaced apart from each other. The plate electrode PE may extend in the first direction D1 and the second direction D2. The plate electrode PE may include at least one selected from metal, metal nitride, and metal silicide.

A metal pattern MP may be provided to overlap in the first direction D1 with at least one of the storage node contacts BC. The metal pattern MP may be provided between the storage node contacts BC. The metal pattern MP may be spaced apart from the back gate electrode BG. The metal pattern MP may include at least one selected from metal, metal nitride, and metal silicide.

A portion of the metal pattern MP may overlap in the third direction D3 with the third dielectric patterns 140. A portion of the metal pattern MP may overlap in the third direction D3 with the back gate electrodes BG.

The metal pattern MP may be between the landing pads LP. The metal pattern MP may be between the plurality of semiconductor patterns SP.

A bottom surface of the metal pattern MP may be located at a level lower than that of bottom surfaces of the storage node contacts BC. A top surface of the metal pattern MP may be located at a level higher than that of top surfaces of the storage node contacts BC. The top surface of the metal pattern MP may be located at a level higher than that of top surfaces of the landing pads LP.

The metal pattern MP may be spaced apart in the first direction D1 and/or the second direction D2 from the storage node contacts BC. The metal pattern MP may be spaced apart in the first direction D1 and/or the second direction D2 from the plurality of semiconductor patterns SP. The metal pattern MP may be spaced apart in the first direction D1 and/or the second direction D2 from the landing pads LP.

The metal pattern MP may have a grid structure that extends in the first and second directions D1 and D2. The metal pattern MP may overlap in the third direction D3 with the shield structure SM. The metal pattern MP may overlap in the third direction D3 with the back gate electrodes BG.

The metal pattern MP may be connected to the plate electrode PE. The metal pattern MP may be in contact with the plate electrode PE. For example, an interface between the metal pattern MP and the plate electrode PE may not be distinguishable, and the metal pattern MP may be a portion of the plate electrode PE.

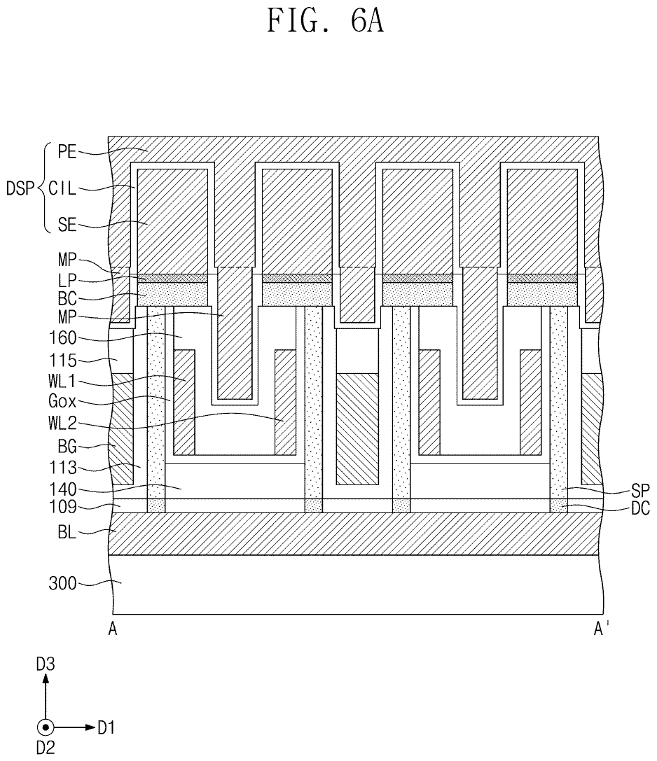

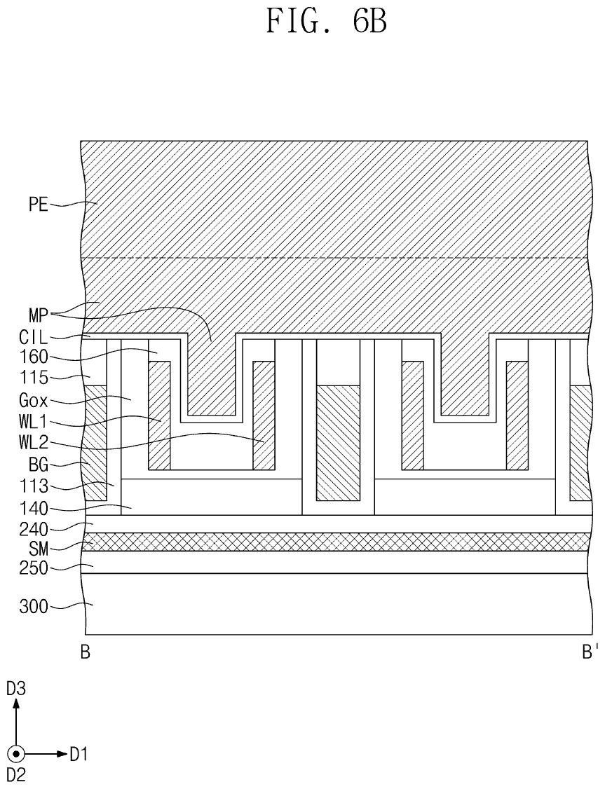

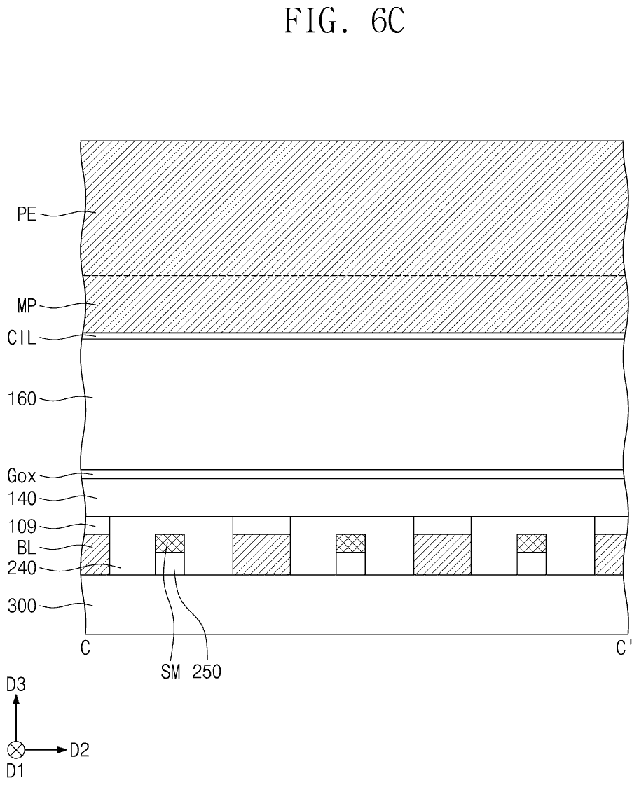

FIGS. 6A, 6B, and 6C illustrate cross-sectional views respectively taken along lines A-A′, B-B′, and C-C′ of FIG. 4, showing a semiconductor device according to some embodiments of the disclosure.

Referring to FIGS. 6A, 6B, and 6C together with FIG. 4, the metal pattern MP may be between the first and second word lines WL1 and WL2. For example, the metal pattern MP may be interposed between the first and second word lines WL1 and WL2 that are adjacent to each other.

A bottom surface of the metal pattern MP may be located at a level lower than that of a top surface of one of the first and second word lines WL1 and WL2. The metal pattern MP may be spaced apart in the first direction D1 from each of the first and second word lines WL1 and WL2.

The separation of the metal pattern MP from the back gate electrodes BG may be the same as in the semiconductor device of FIGS. 5A, 5B, and 5C. For example, the bottom surface of the metal pattern MP may be located at a level that is different between a portion of the metal pattern MP that overlaps in the third direction D3 with the back gate electrode BG and a portion of the metal pattern that is between the first and second word lines WL1 and WL2. The bottom surface of a portion of the metal pattern MP between the first and second word lines WL1 and WL2 may be located at a level lower than that of a portion of the metal pattern MP that overlaps in third direction D3 with the back gate electrodes BG.

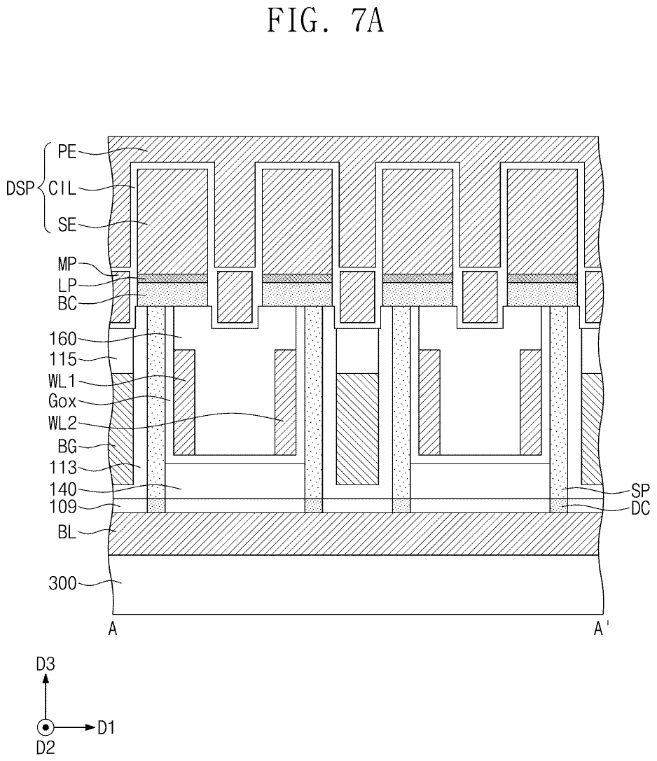

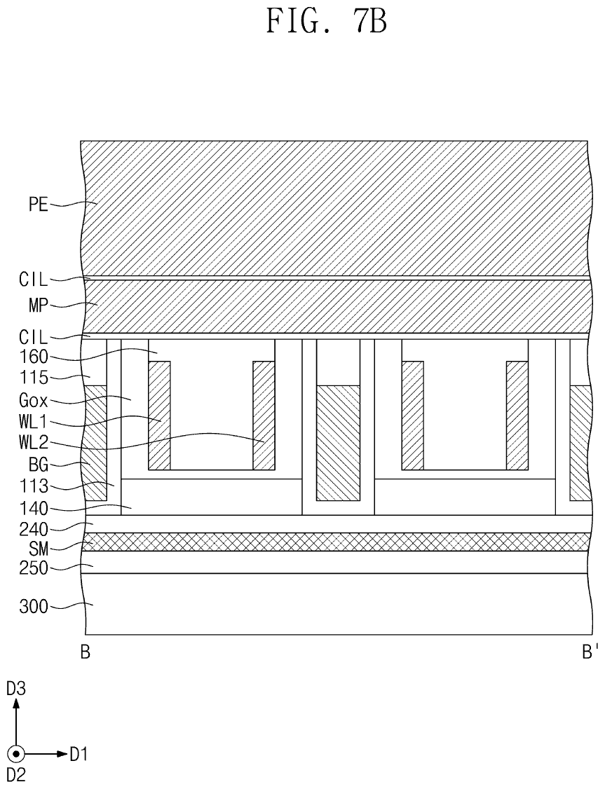

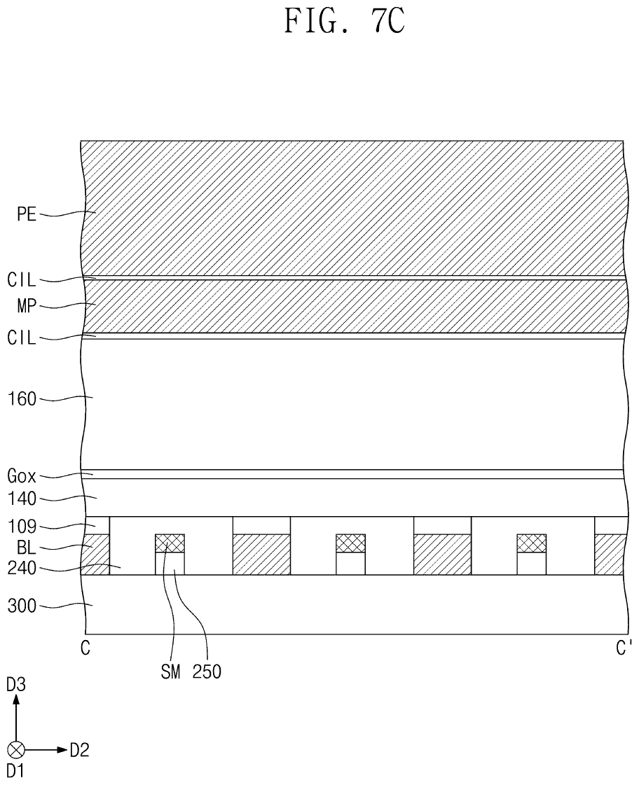

FIGS. 7A, 7B, and 7C illustrate cross-sectional views respectively taken along lines A-A′, B-B′, and C-C′ of FIG. 4, showing a semiconductor device according to some embodiments of the disclosure.

Referring to FIGS. 7A, 7B, and 7C together with FIG. 4, the metal pattern MP may be spaced apart in the third direction D3 from the plate electrode PE. The capacitor dielectric layer CIL may be between the metal pattern MP and the plate electrode PE that are connected into a single unitary piece.

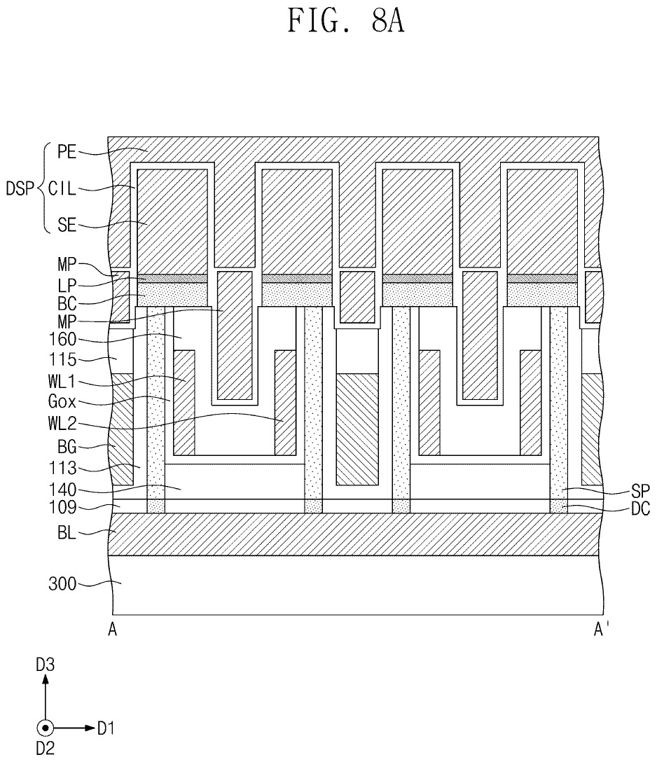

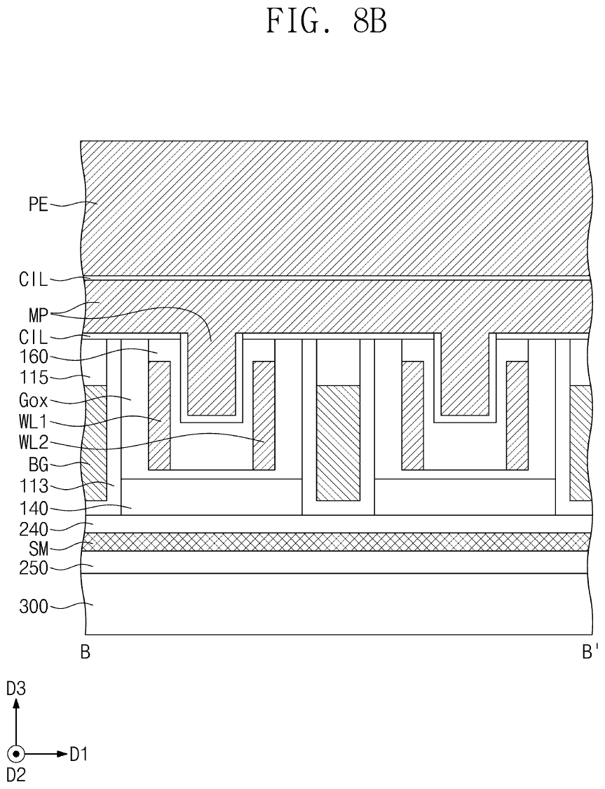

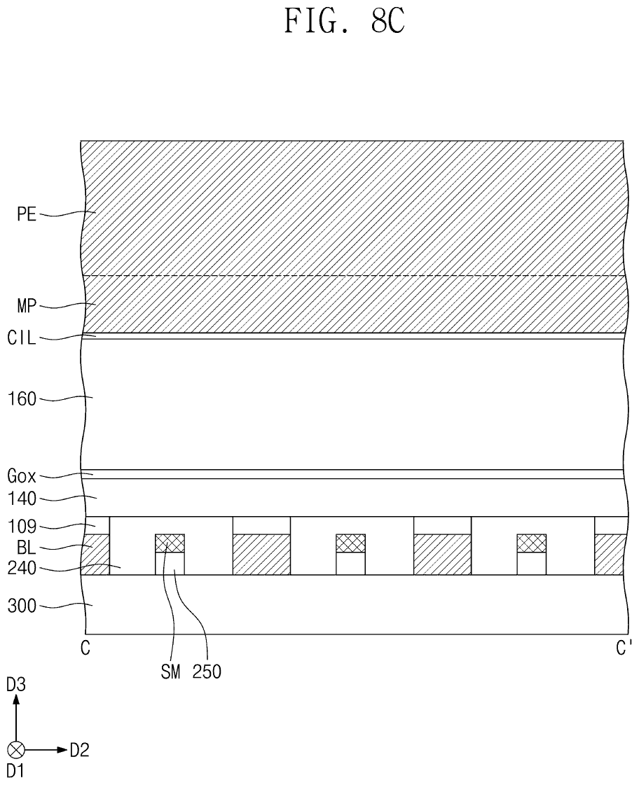

FIGS. 8A, 8B, and 8C illustrate cross-sectional views respectively taken along lines A-A′, B-B′, and C-C′ of FIG. 4, showing a semiconductor device according to some embodiments of the disclosure.

Referring to FIGS. 8A, 8B, and 8C together with FIG. 4, the metal pattern MP may be spaced apart in the third direction D3 from the plate electrode PE. A bottom surface of the metal pattern MP may be located at a level lower than that of a top surface of one of the first and second word lines WL1 and WL2. The metal pattern MP may be spaced apart in the first direction D1 from each of the first and second word lines WL1 and WL2.

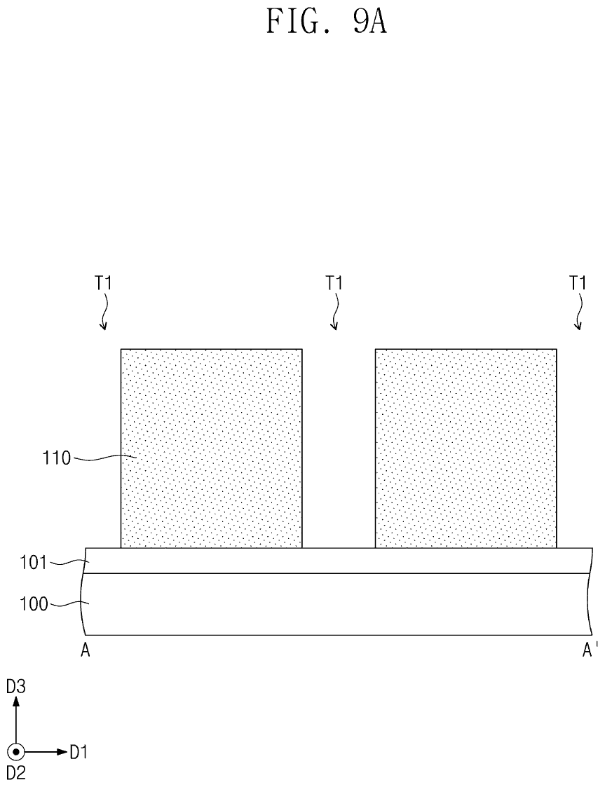

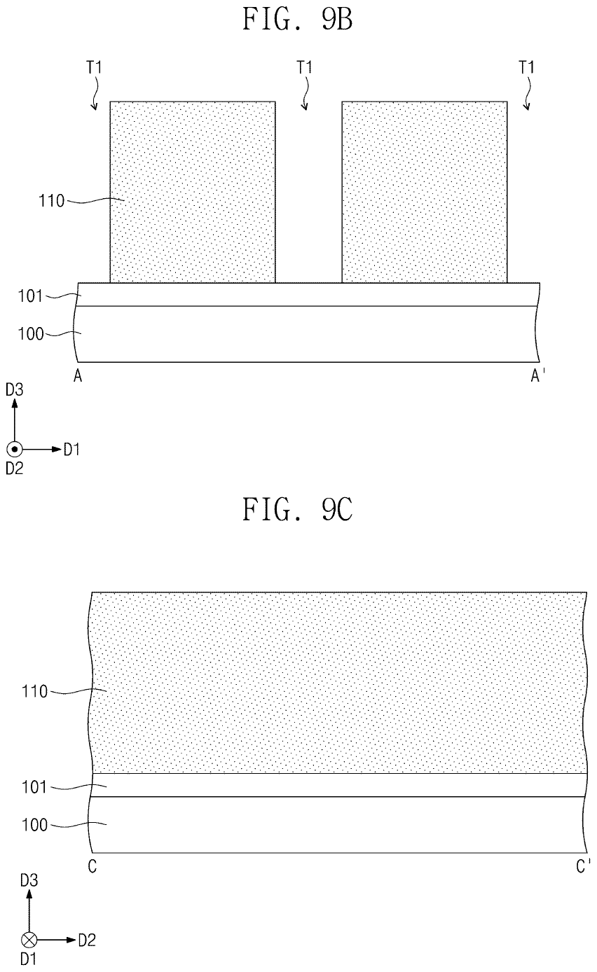

FIGS. 9A to 9C, 10A to 10C, 11A to 11C, 12A to 12C, 13A to 13C, 14A to 14C, 15A to 15C, 16A to 16C, 17A to 17C, 18A to 18C and 19A to 19C illustrate cross-sectional views showing a method of fabricating a semiconductor device according to some embodiments of the disclosure. In detail, FIGS. 9A, 10A, 11A, 12A, 13A, 14A, 15A, 16A, 17A, 18A, and 19A illustrate cross-sectional views taken along line A-A′ of FIG. 4. FIGS. 9B, 10B, 11B, 12B, 13B, 14B, 15B, 16B, 17B, 18B, and 19B illustrate cross-sectional views taken along line B-B′ of FIG. 4. FIGS. 9C, 10C, 11C, 12C, 13C, 14C, 15C, 16C, 17C, 18C, and 19C illustrate cross-sectional views taken along line C-C′ of FIG. 4. With reference to FIGS. 4 and 9A to 19C, the following will describe a method of fabricating the semiconductor device according to FIGS. 4 and 5A to 5C. For brevity of description, a repetitive description will be omitted.

Referring to FIGS. 4 and 9A to 9C, according to an embodiment, the method may include forming a substrate structure. For example, forming the substrate structure may include forming a first substrate 100, a buried dielectric layer 101, and an active layer 110. The substrate structure may be a silicon-on-insulator (SOI) substrate.

The first substrate 100 may be, for example, a silicon substrate, a germanium substrate, and/or a silicon-germanium substrate.

The buried dielectric layer 101 may be buried oxide (BOX) formed by a separation by implanted oxygen (SIMOX) method or a bonding and layer transfer method. However, the disclosure is not limited thereto, and as such, according to another embodiment, the buried dielectric layer 101 may be a dielectric layer formed by a chemical vapor deposition process. The buried dielectric layer 101 may include, but is not limited to, one or more of a silicon oxide layer, a silicon nitride layer, a silicon oxynitride layer, and a low-k dielectric layer.

The active layer 110 may be a monocrystalline semiconductor layer. The active layer 110 may include, but is not limited to, a silicon substrate, a germanium substrate, and/or a silicon-germanium substrate.

According to an embodiment, after forming the active layer 110, first trenches T1 may be formed on the first substrate 100. The formation of the first trenches T1 may include, for example, forming a mask pattern on the active layer 110, and using the mask pattern as an etching mask to etch the active layer 110. The first trenches T1 may expose the buried dielectric layer 101. The first trenches T1 may be spaced apart from each other in a first direction D1.

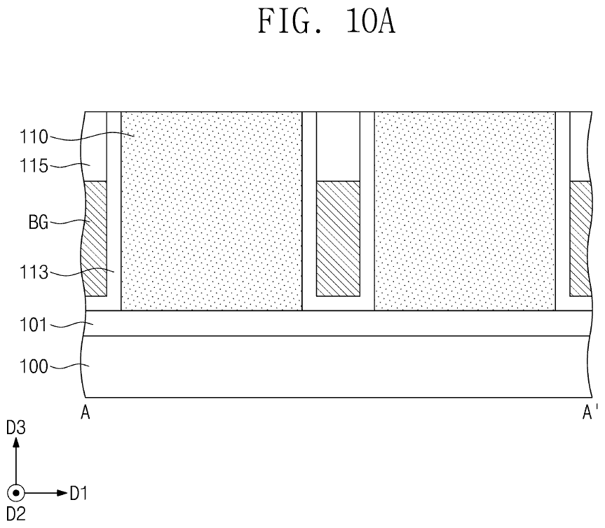

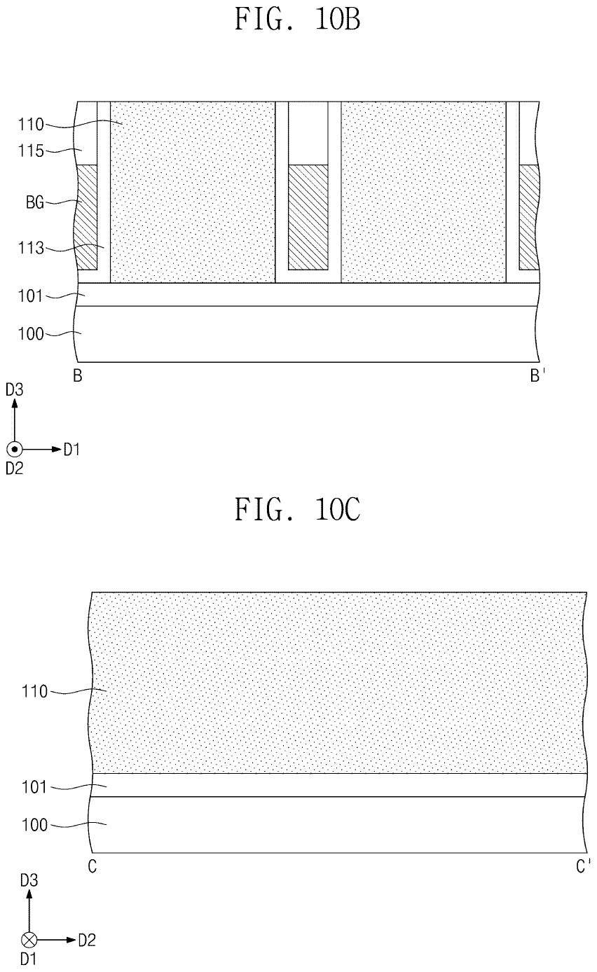

Referring to FIGS. 4 and 10A to 10C, back gate dielectric patterns 113 and back gate electrodes BG may be formed in the first trenches T1. According to an embodiment, back gate capping patterns 115 may be formed. For example, the back gate capping patterns 115 may be formed on the back gate electrodes BG.

According to an embodiment, the method of forming the back gate dielectric patterns 113 and the back gate electrodes BG may include, for example, depositing a back gate dielectric layer that conformally covers sidewalls of the first trenches T1, depositing a back gate conductive layer in unoccupied portions of the first trenches T1 in which the back gate dielectric layer is deposited, and etching the back gate dielectric layer and the back gate conductive layer. Each of the back gate dielectric patterns 113 may be provided on corresponding sidewall of the first trench T1. For example, each of the back gate dielectric patterns 113 may conformally cover a corresponding sidewall of the first trench T1. Each of the back gate electrodes BG may be formed on a corresponding back gate dielectric pattern 113. The back gate electrodes BG may be spaced apart from the active layers 110 across the back gate dielectric patterns 113.

According to some embodiments, before the formation of the back gate dielectric patterns 113, a gas-phase doping process (GPD) or a plasma doping process (PLAD) may be performed to dope impurities into the active layers 110 exposed through the sidewalls of the first trenches T1.

According to an embodiment, the method of forming the back gate capping patterns 115 may include, for example, forming a back gate capping layer that fills unoccupied portions of the first trenches T1 and etching the back gate capping layer.

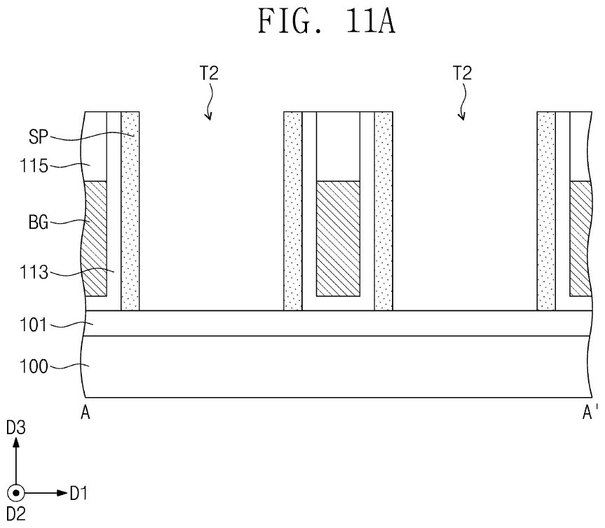

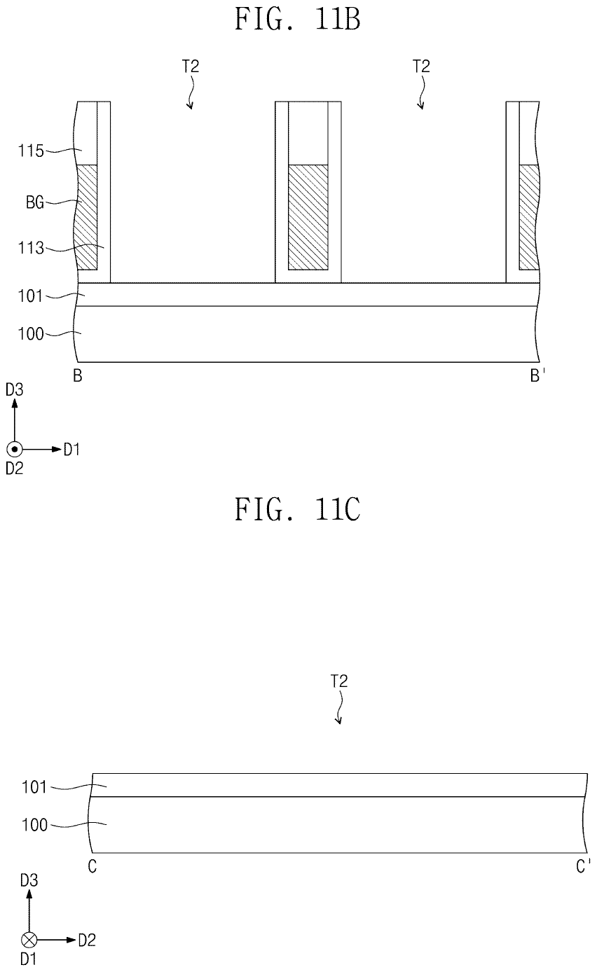

Referring to FIGS. 4 and 11A to 11C, according to an embodiment, the method may include forming a plurality of semiconductor patterns SP.

According to an embodiment, the method of forming the plurality of semiconductor patterns SP may include forming a mask pattern on the active layer 110, the back gate dielectric pattern 113, and the back gate capping pattern 115, and using the mask pattern as an etching mask to etch the active layer 110 to form second trenches T2. The second trenches T2 may expose the buried dielectric layer 101.

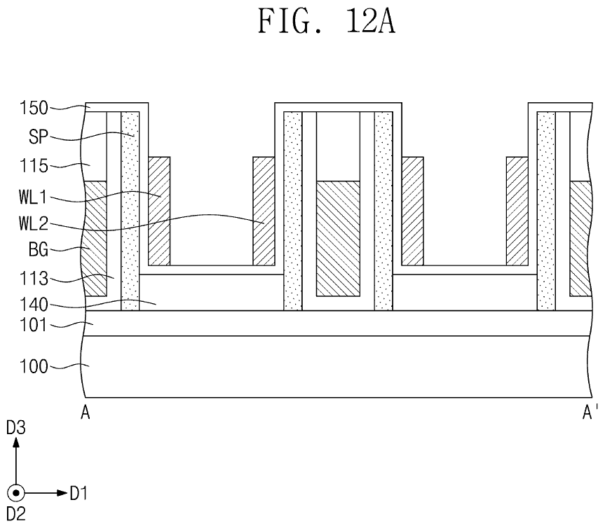

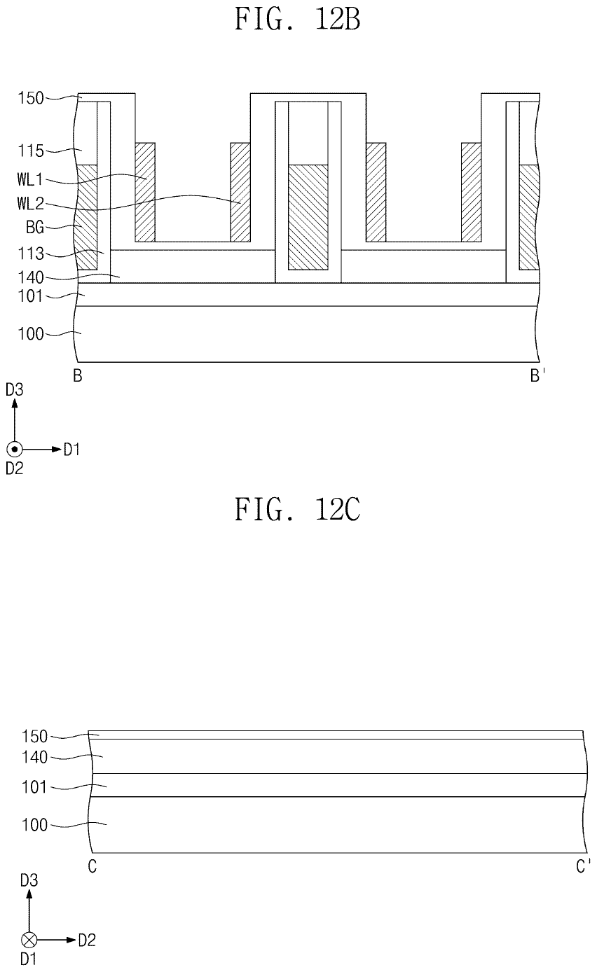

Referring to FIGS. 4 and 12A to 12C, according to an embodiment, the method may include forming third dielectric patterns 140 and a gate dielectric layer 150. Thereafter, according to an embodiment, the method may include forming first and second word lines WL1 and WL2. An ordinary procedure may be employed to form the third dielectric patterns 140 and the gate dielectric layer 150.

The first and second word lines WL1 and WL2 may be spaced apart from the semiconductor pattern SP across the gate dielectric layer 150. The formation of the first and second word lines WL1 and WL2 may include, for example, forming a word-line layer on the gate dielectric layer 150 and performing an etching process on the word-line layer. The first and second word lines WL1 and WL2 may have their top surfaces located at a level lower than that of a top surface of the gate dielectric layer 150.

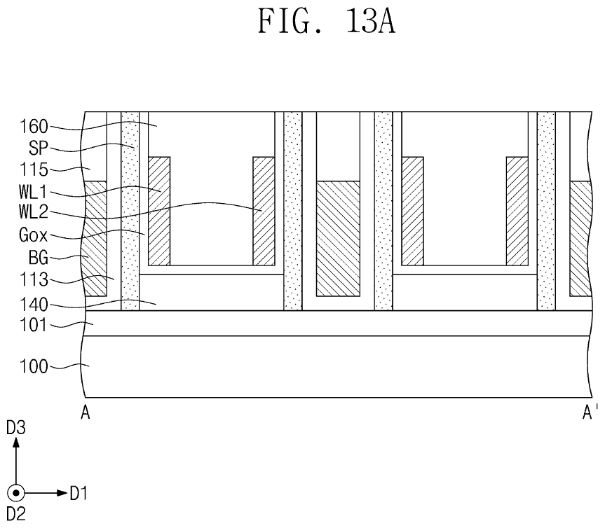

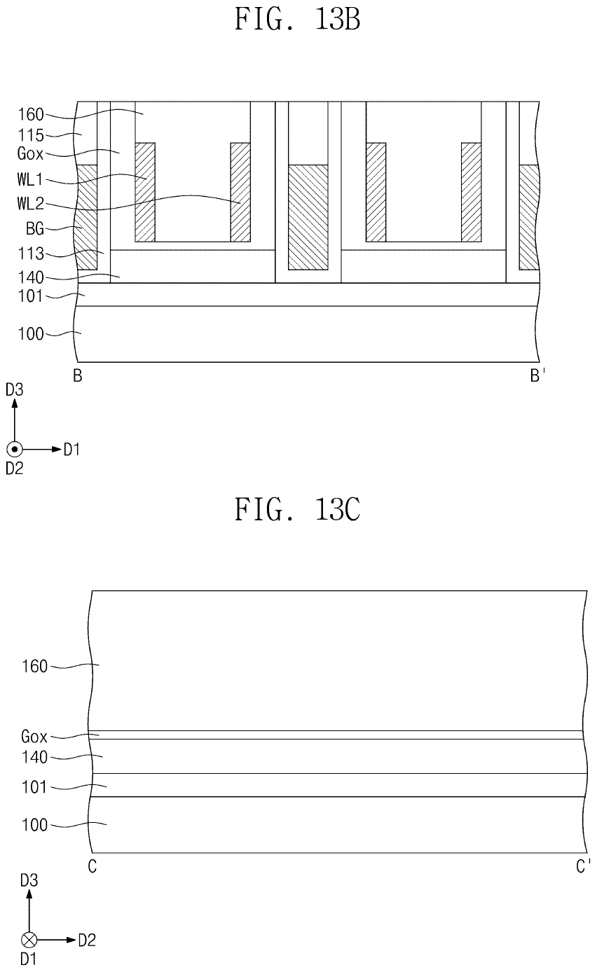

Referring to FIGS. 4 and 13A to 13C, according to an embodiment, the method may include forming second dielectric patterns 160 to fill spaces between the first and second word lines WL1 and WL2. In addition, according to an embodiment, the method may include forming gate dielectric patterns Gox. According to an embodiment, the method of forming the second dielectric patterns 160 and the gate dielectric patterns Gox may include, for example, forming a second dielectric pattern layer and planarizing the gate dielectric layer 150 and the third dielectric pattern layer until top surfaces of the back gate capping patterns 115 are exposed.

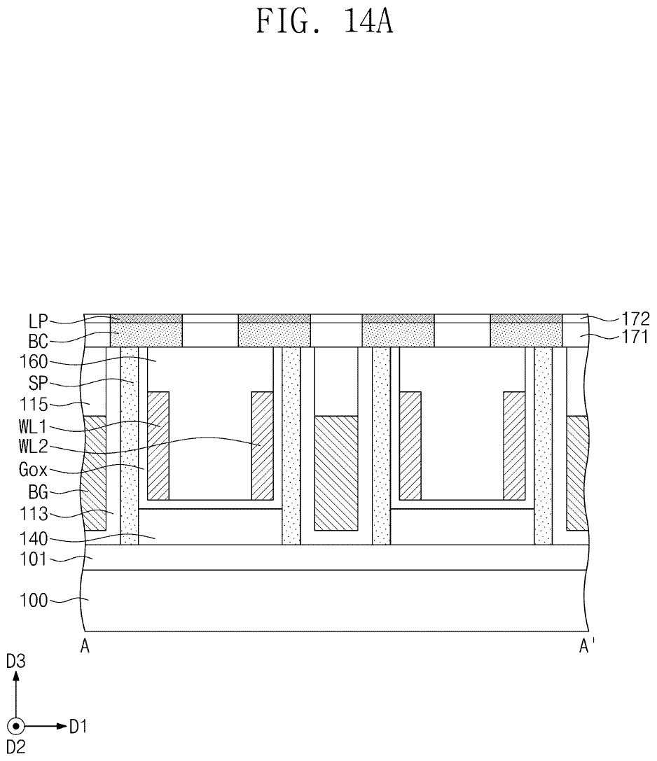

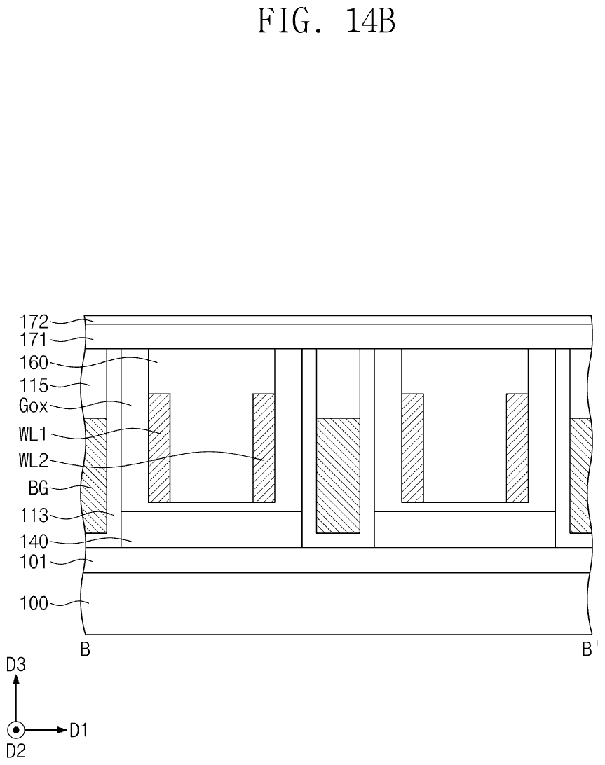

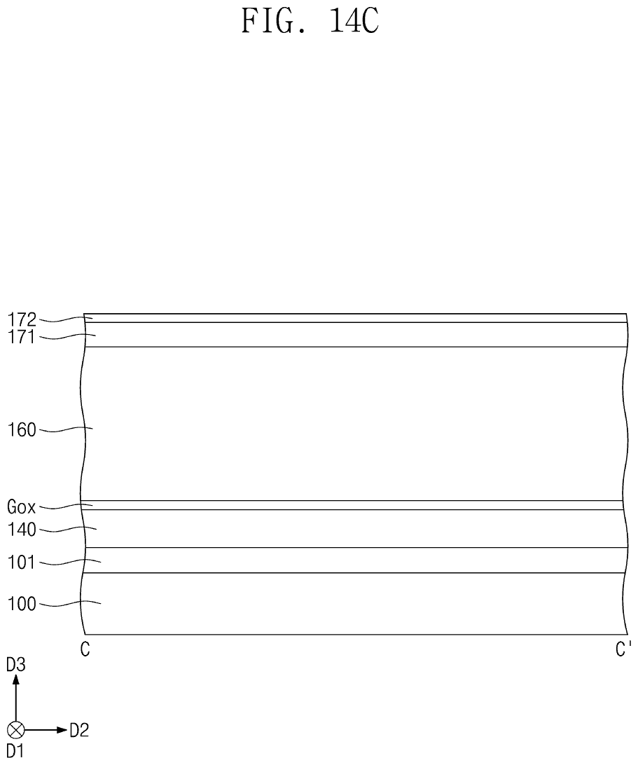

Referring to FIGS. 4 and 14A to 14C, according to an embodiment, the method may include forming an upper dielectric layer 171 on an upper surface of the first substrate 100. According to an embodiment, the method may include forming, storage node contacts BC to penetrate the upper dielectric layer 171. For example, the storage node contacts BC may penetrate the upper dielectric layer 171 to come into connection with corresponding semiconductor patterns SP.

According to an embodiment, the method of forming the storage node contacts BC may include, for example, etching the upper dielectric layer 171 to form holes that expose first and second vertical parts, depositing a conductive layer that fills the holes, and planarizing the conductive layer to expose a top surface of the upper dielectric layer 171.

According to an embodiment, the method may include forming a separation dielectric layer 172 on the upper dielectric layer 171. According to an embodiment, the method may include forming landing pads LP on the dielectric layer 172. For example, the landing pads LP may be formed to penetrate the separation dielectric layer 172 to come into connection with corresponding storage node contacts BC. According to an embodiment, the method of forming the landing pads LP may include, for example, etching the separation dielectric layer 172 to form holes that expose the storage node contacts BC, depositing a conductive layer that fills the holes, and planarizing the conductive layer to expose a top surface of the separation dielectric layer 172.

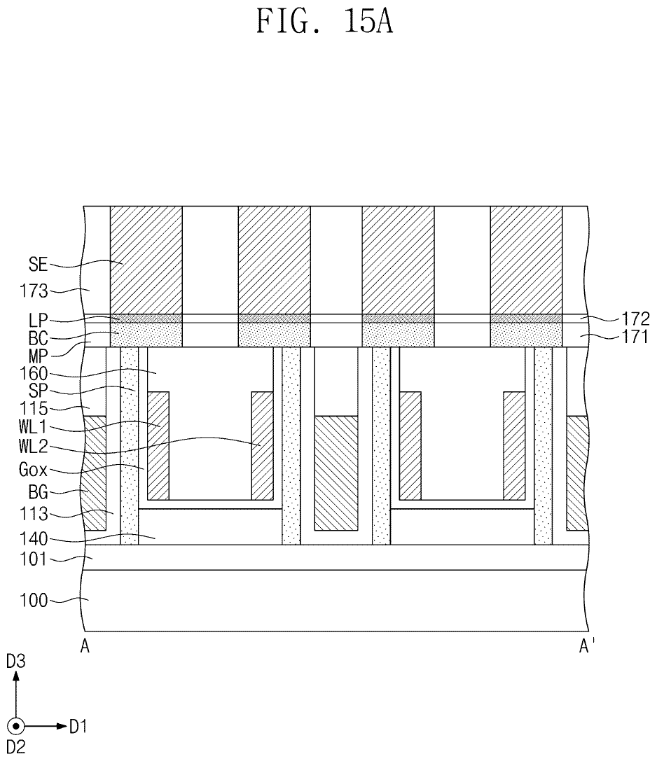

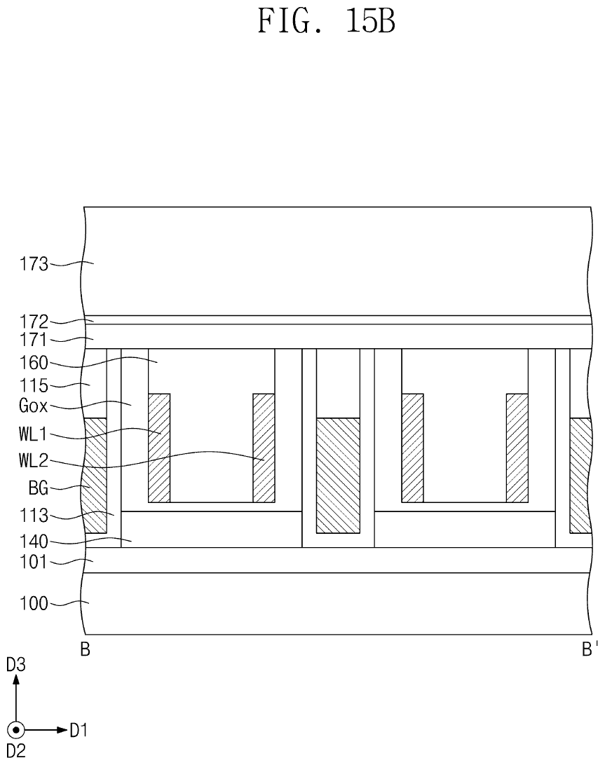

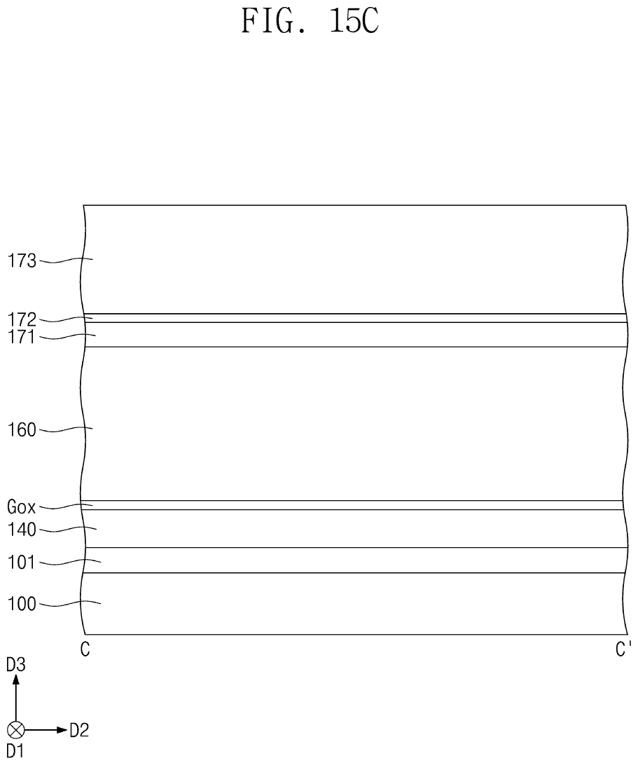

Referring to FIGS. 4 and 15A to 15C, according to an embodiment, the method may include forming storage electrodes SE. According to an embodiment, the method of forming the storage electrodes SE may include forming a storage electrode layer and patterning the storage electrode layer to form storage electrodes SE. Afterwards, a dielectric pattern 173 may be formed to fill the storage electrodes SE, and for example, the dielectric pattern 173 may include at least one selected from silicon oxide, silicon nitride, silicon oxynitride, and low-k dielectrics.

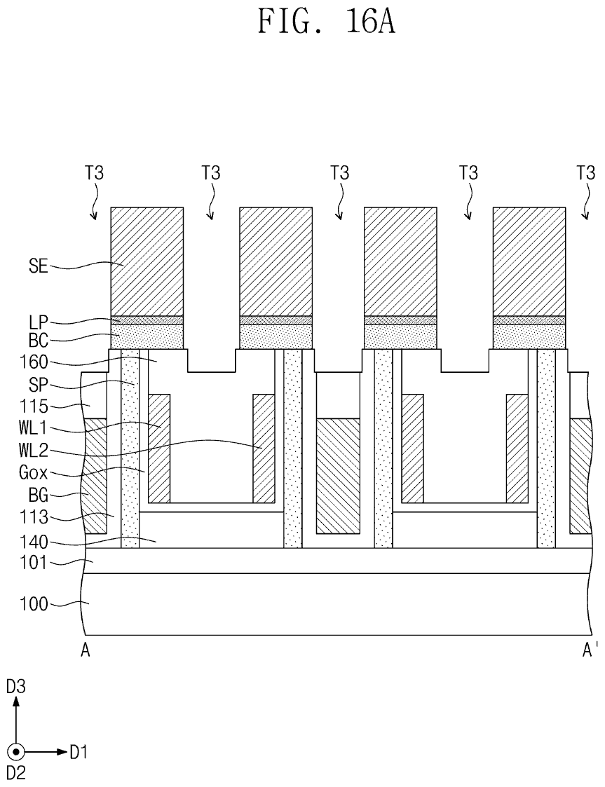

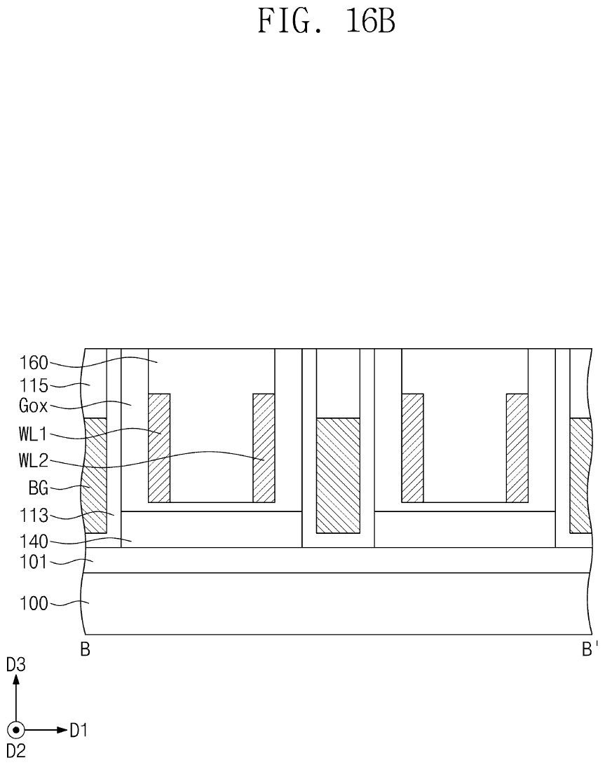

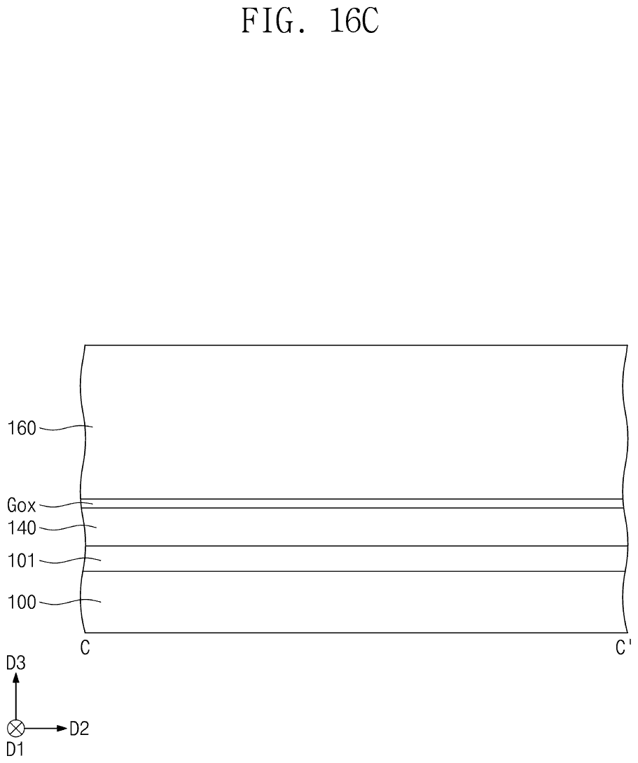

Referring to FIGS. 4 and 16A to 16C, according to an embodiment, the method may include forming third trenches T3. According to an embodiment, the method of forming the third trenches T3 may include removing the dielectric pattern 173, removing the separation dielectric layer 172, and removing the upper dielectric layer 171. According to an embodiment, the method of forming the third trenches T3 may include partially removing the second dielectric patterns 160, the back gate dielectric pattern 113, and the back gate capping pattern 115.

In the case of fabricating the semiconductor devices according to FIGS. 5A to 5C and 7A to 7C, the third trenches T3 may have substantially the same depth.

In the case of fabricating the semiconductor devices according to FIGS. 6A to 6C and 8A to 8C, the third trenches T3 that overlap in a third direction D3 with the third dielectric patterns 140 may have their depth different from that of the third trenches T3 that overlap in the third direction D3 with the back gate electrodes BG. The depth of the third trenches T3 that overlap in the third direction D3 with the third dielectric patterns 140 may be greater than that of the third trenches T3 that overlap in the third direction D3 with the back gate electrodes BG.

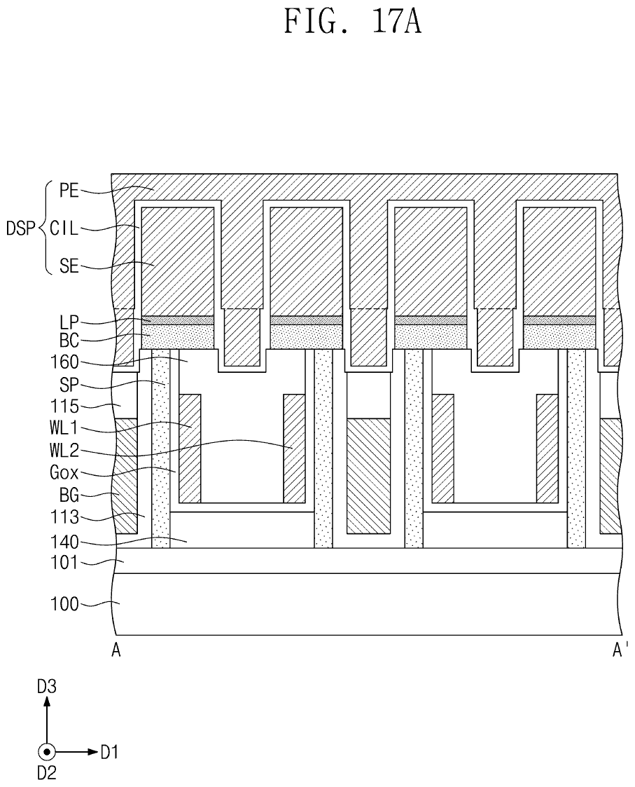

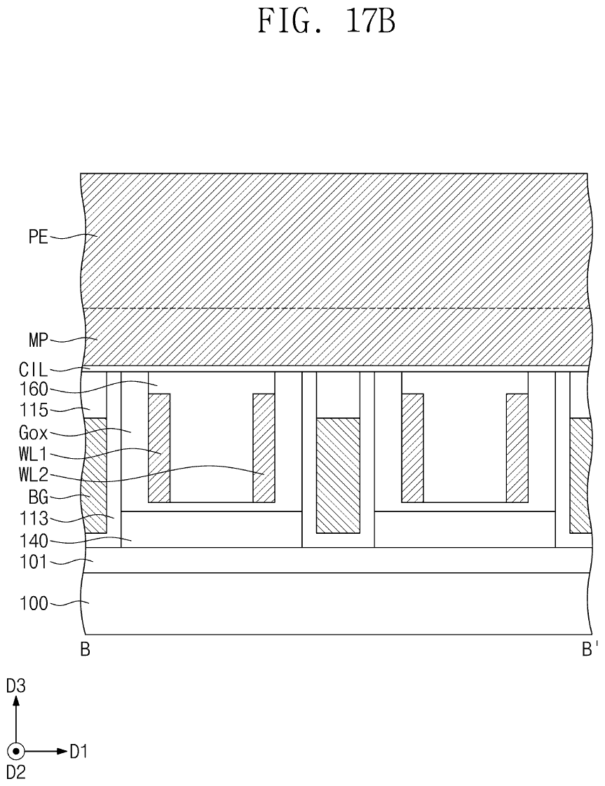

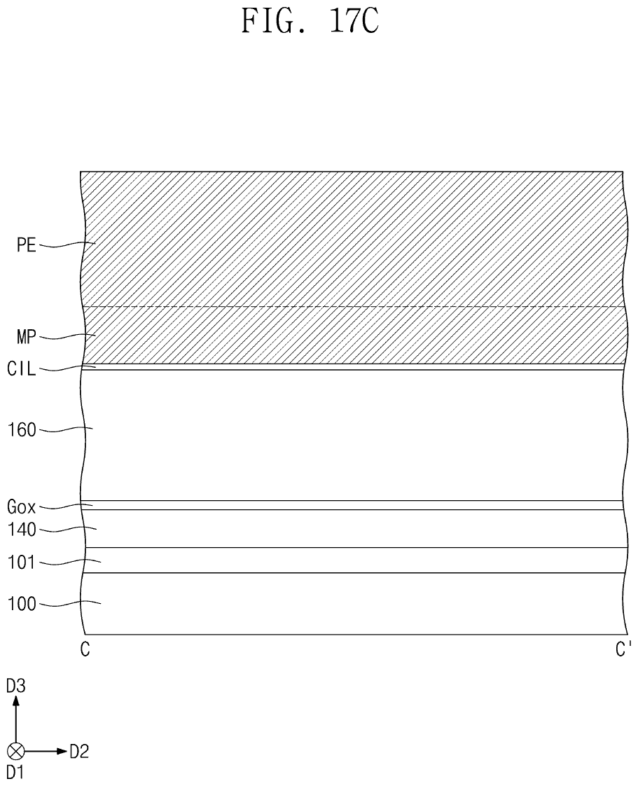

Referring to FIGS. 4 and 17A to 17C, according to an embodiment, the method may include forming a capacitor dielectric layer CIL on the storage electrodes SE. For example, the capacitor dielectric layer CIL may be formed to conformally cover the storage electrodes SE. According to an embodiment, the method may include forming a metal pattern MP and a plate electrode PE on the capacitor dielectric layer CIL. Accordingly, a data storage pattern DSP may be formed which includes the storage electrodes SE, the capacitor dielectric layer CIL, and the plate electrode PE.

In the case of fabricating the semiconductor devices according to FIGS. 5A to 5C and FIGS. 7A to 7C, after the formation of the capacitor dielectric layer CIL, the metal pattern MP and the plate electrode PE may be formed on the capacitor dielectric layer CIL.

In the case of fabricating the semiconductor devices according to FIGS. 6A to 6C and 8A to 8C, the metal pattern MP may be formed after the formation of the capacitor dielectric layer CIL that conformally covers the storage electrodes SE. After that, after the formation of the capacitor dielectric layer CIL that covers a top surface of the metal pattern MP, the plate electrode PE may be formed.

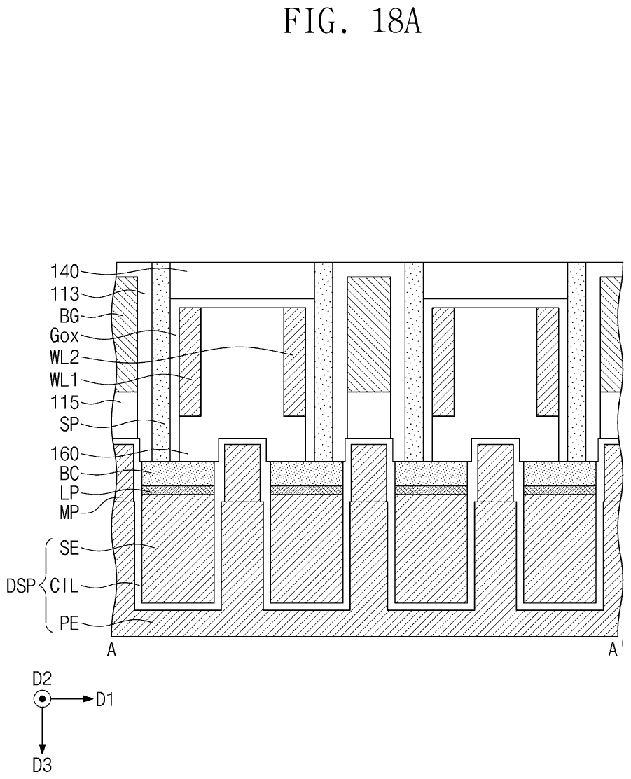

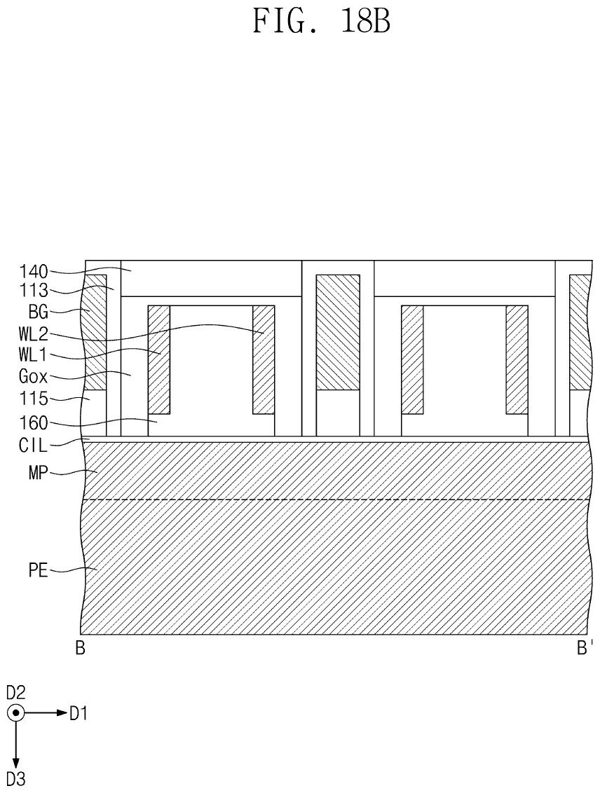

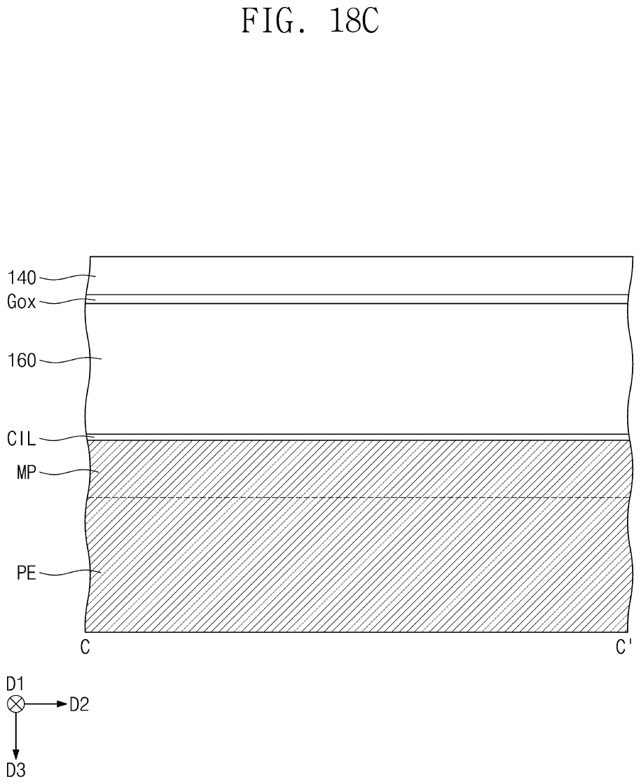

Referring to FIGS. 4 and 18A to 18C, after the formation of the data storage pattern DSP, a semiconductor device being fabricated may be turned upside down. For example, a semiconductor device may be flipped to allow the date storage pattern DSP to face downward. According to an embodiment, the method may include removing the first substrate 100 after flipping the semiconductor device. After the removal of the first substrate 100, a buried dielectric layer 101 may be additionally removed. The removal of the first substrate 100 and the buried dielectric layer 101 may include planarizing the first substrate 100 and the buried dielectric layer 101 until the plurality of semiconductor patterns SP are exposed. The planarization may be achieved through a chemical mechanical polishing (CMP) process.

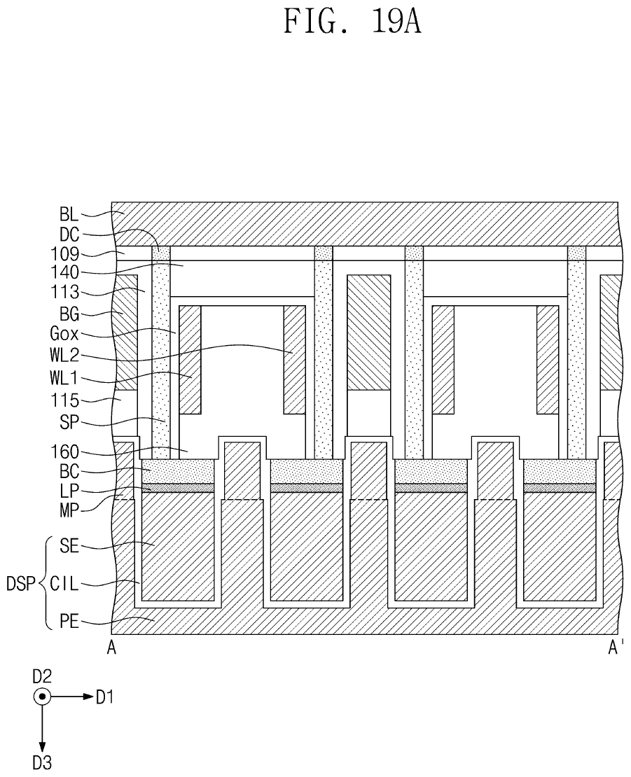

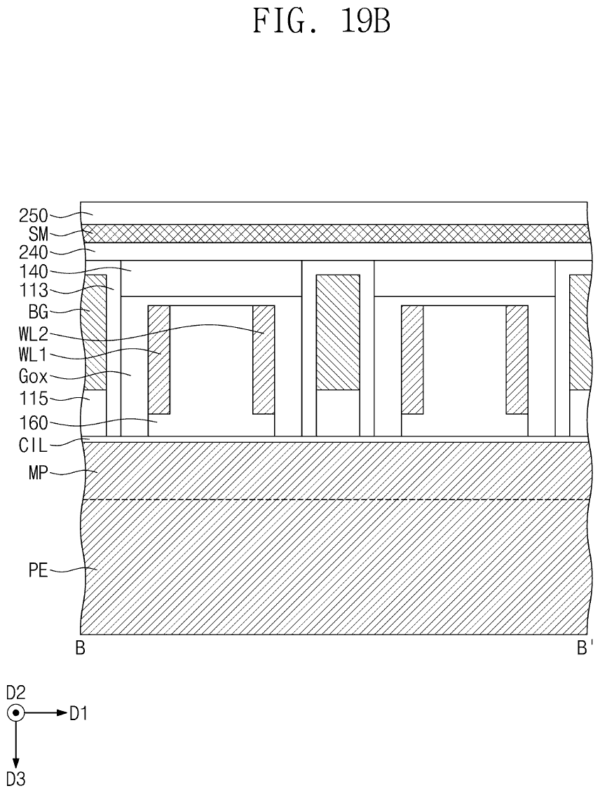

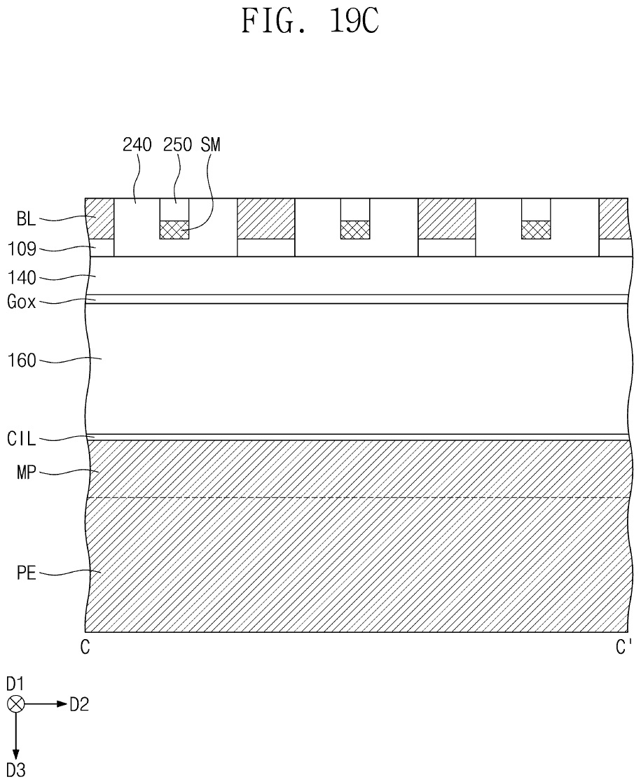

Referring to FIGS. 4 and 19A to 19C, a first dielectric pattern 109, a bit-line contact DC, and a bit line BL may be stacked on the plurality of semiconductor patterns SP and the third dielectric pattern 140.

According to an embodiment, the method of forming the first dielectric pattern 109 and the bit-line contact DC may include forming a first dielectric layer, etching the first dielectric layer to form a hole, and forming the bit-line contact DC on the hole. According to an embodiment, the method of forming the bit line BL may include, for example, forming a bit-line layer and etching the bit-line layer.

After the formation of the plurality of bit lines BL, a first dielectric layer 240, shield structures SM, and a second dielectric layer 250 may be formed between the plurality of bit lines BL that are spaced apart from each other in a second direction D2. The formation of the first dielectric layer 240, the shield structures SM, and the second dielectric layer 250 may include, for example, forming a preliminary first dielectric layer on an upper surface of the semiconductor device being fabricated, depositing the shield structures SM in a space between the preliminary first dielectric layer, forming a preliminary second dielectric layer on the upper surface of the semiconductor device being fabricated, and planarizing the preliminary second dielectric layer and the preliminary first dielectric layer until a top surface of the bit line BL is exposed.

Referring back to FIGS. 4 and 5A to 5C, a substrate 300 may be bonded to the semiconductor device being fabricated. After the bonding of the substrate 300, the semiconductor device being fabricated may be turned upside down. For example, the substrate 300 may be flipped to face downward.

In a semiconductor according to the disclosure, a metal pattern may shield potentials of storage node contacts. For example, the metal pattern may be provided between contacts of the storage nodes. In this manner, interference resulting from a difference in potential between the contacts of storage nodes may be reduced/eliminated. Thus, a capacitor may have increased capacitance, and a leakage current may improve. As a result, it may be possible to provide a semiconductor device with improved reliability and electrical properties.

Although the inventive concepts have been described in connection with the some embodiments of the disclosure illustrated in the accompanying drawings, it will be understood by one of ordinary skill in the art that variations in form and detail may be made therein without departing from the spirit and essential feature of the inventive concepts. The above disclosed embodiments should thus be considered illustrative and not restrictive.

What is claimed is:

1. A semiconductor device, comprising:
a bit line that extends in a first direction;
a plurality of semiconductor patterns provided on the bit line, the plurality of semiconductor patterns extending in a second direction perpendicular to an upper surface of the bit line;
a first word line and a second word line between the plurality of semiconductor patterns and spaced apart from each other in the first direction, the first and second word lines extending in a third direction perpendicular to the first direction and the second direction;
a plurality of storage node contacts provided on the plurality of semiconductor patterns; and
a metal pattern between the plurality of storage node contacts.

2. The semiconductor device of claim 1, wherein the plurality of semiconductor patterns comprise a monocrystalline semiconductor material.

3. The semiconductor device of claim 1, further comprising a data storage pattern provided on the plurality of storage node contacts,
wherein the data storage pattern comprises:
a plurality of storage electrodes provided on the plurality of storage node contacts; and
a plate electrode between the plurality of storage electrodes.

4. The semiconductor device of claim 3, wherein the metal pattern is spaced apart from the plate electrode in the second direction.

5. The semiconductor device of claim 3, wherein the metal pattern comprises a portion of the plate electrode.

6. The semiconductor device of claim 3, further comprising a plurality of landing pads between the plurality of storage node contacts and the data storage pattern,
wherein the metal pattern is between the plurality of landing pads.

7. The semiconductor device of claim 1, wherein the metal pattern is between the first word line and the second word line.

8. The semiconductor device of claim 1, wherein the metal pattern is between the plurality of semiconductor patterns.

9. The semiconductor device of claim 1, further comprising a plurality of back gate electrodes provided on the bit line,
wherein the metal pattern is spaced apart from the plurality of back gate electrodes.

10. A semiconductor device, comprising:
a bit line that extends in a first direction;
a plurality of semiconductor patterns provided on the bit line, the plurality of semiconductor patterns extending in a second direction perpendicular to an upper surface of the bit line;
a first word line and a second word line between the plurality of semiconductor patterns and spaced apart from each other in the first direction, the first and second word lines extending in a third direction perpendicular to the first direction and the second direction;
a plurality of storage node contacts provided on the plurality of semiconductor patterns; and
a metal pattern between the plurality of storage node contacts,
wherein a bottom surface of the metal pattern is at a first level lower than a second level of bottom surfaces of the plurality of storage node contacts.

11. The semiconductor device of claim 10, wherein the first level of the bottom surface of the metal pattern is lower than a third level of a top surface of one of the first word line and the second word line.

12. The semiconductor device of claim 10, wherein a top surface of the metal pattern is at a third level higher than a fourth level of top surfaces of the plurality of storage node contacts.

13. The semiconductor device of claim 10, further comprising:
a plurality of landing pads provided on the plurality of storage node contacts; and
a data storage pattern provided on the plurality of landing pads,
wherein the data storage pattern comprises:
a plurality of storage electrodes provided on the plurality of storage node contacts; and
a plate electrode between the plurality of storage electrodes.

14. The semiconductor device of claim 13, wherein a top surface of the metal pattern is at a third level higher than a fourth level of top surfaces of the plurality of landing pads.

15. The semiconductor device of claim 13, wherein the metal pattern is connected to the plate electrode.

16. A semiconductor device, comprising:
a bit line that extends in a first direction;
a plurality of semiconductor patterns provided on the bit line, the plurality of semiconductor patterns extending in a second direction perpendicular to an upper surface of the bit line;
a first word line and a second word line between the plurality of semiconductor patterns and spaced apart from each other in the first direction, the first and second word lines extending in a third direction perpendicular to the first direction and the second direction;
a plurality of storage node contacts provided on the plurality of semiconductor patterns; and
a metal pattern spaced apart in the first direction or the third direction from the plurality of storage node contacts,
wherein the metal pattern extends in the first direction and the third direction.

17. The semiconductor device of claim 16, further comprising a data storage pattern on the plurality of storage node contacts,
wherein the data storage pattern comprises:
a plurality of storage electrodes provided on the plurality of storage node contacts; and
a plate electrode between the plurality of storage electrodes, and
wherein the metal pattern is in contact with the plate electrode.

18. The semiconductor device of claim 16, wherein the metal pattern is spaced apart in the first direction or the third direction from the plurality of semiconductor patterns.

19. The semiconductor device of claim 16, wherein the metal pattern is spaced apart in the first direction from each of the first word line and the second word line.

20. The semiconductor device of claim 16, further comprising a plurality of landing pads provided on the plurality of storage node contacts,
wherein the metal pattern is spaced in the first direction or the third direction from the plurality of landing pads.
